(19) United States
(12) Patent Application Publication
(10) Pub. No.: US 2026/0018213 A1
(43) Pub. Date: Jan. 15, 2026

(54) MEMORY DEVICES, MEMORY SYSTEMS, AND OPERATION METHODS THEREOF

(71) Applicant: YANGTZE MEMORY TECHNOLOGIES CO., LTD., Wuhan (CN)

(72) Inventors: Yang Zhang, Wuhan (CN); Dong He, Wuhan (CN); Masao Kuriyama, Wuhan (CN)

(21) Appl. No.: 18/773,950

(22) Filed: Jul. 16, 2024

(30) Foreign Application Priority Data
Jul. 9, 2024 (CN) 202410917236.5

(51) Int. Cl. G11C 16/16; G11C 16/08; G11C 16/34

(52) U.S. Cl. CPC G11C 16/16; G11C 16/08; G11C 16/3445

(57) ABSTRACT

In certain aspects, a method of operating a memory device is disclosed. A first block and a second block are selected from the memory device. The memory device includes a plurality of blocks including the first block, the second block, and a third block located between the first and second blocks in a plane of the memory device. The third block is unselected while the first and second blocks are being selected. A first erase operation is performed on the first and second blocks in a first period of time.

### CROSS-REFERENCE TO RELATED APPLICATIONS

This application claims the benefit of priority to Chinese Application No. 202410917236.5, filed on July 9, 2024, the content of which is incorporated herein by reference in its entirety.

### BACKGROUND

The present disclosure relates to memory devices, memory systems, and operation methods thereof.

Non-volatile storage devices such as solid-state drives (SSDs), non-volatile memory express (NVMe), embedded multimedia cards (eMMCs), and universal flash storage (UFS) devices, etc., have gained significant popularity in recent years due to their numerous advantages over traditional hard disk drives (HDDs), such as faster read and write speed, durability and reliability, reduced power consumption, silent operation, and smaller form factors. For example, non-volatile storage devices such as SSDs may use NAND Flash memory for non-volatile storage. Various operations can be performed by NAND Flash memory, such as read, program (write), and erase. For NAND Flash memory, an erase operation can be performed at the block level, and a program operation or a read operation can be performed at the page level.

### SUMMARY

In one aspect, a method of operating a memory device is disclosed. A first block and a second block are selected from the memory device. The memory device includes a plurality of blocks including the first block, the second block, and a third block located between the first and second blocks in a plane of the memory device. The third block is unselected while the first and second blocks are being selected. A first erase operation is performed on the first and second blocks in a first period of time.

In some implementations, the method further includes selecting the third block from the memory device, and performing a second erase operation on the third block in a second period of time that is different from the first period of time.

In some implementations, the memory device includes a peripheral circuit coupled to the plurality of blocks. Selecting the first block and the second block from the memory device includes: unselecting, by the peripheral circuit, the plurality of blocks; and for each block in the first and second blocks, responsive to receiving a block address of the corresponding block, generating, by the peripheral circuit, a block-select signal having a block-select value to select the corresponding block. The block-select signal is stored in a block address latch associated with the corresponding block.

In some implementations, unselecting the plurality of blocks includes resetting, by the peripheral circuit, a plurality of block address latches associated with the plurality of blocks to an unselect state, so that the plurality of blocks are unselected.

In some implementations, generating the block-select signal further includes, responsive to receiving the block address of the corresponding block and a state of a block labeling latch associated with the corresponding block indicating that the corresponding block is a functioning block, generating the block-select signal having the block-select value.

In some implementations, the memory device includes a peripheral circuit coupled to the plurality of blocks. Selecting the first block and the second block from the memory device includes: labeling, by the peripheral circuit, the plurality of blocks as bad blocks; relabeling, by the peripheral circuit, the first and second blocks as functioning blocks; and selecting, by the peripheral circuit, the first and second blocks relabeled as the functioning blocks based on a select-all-block signal.

In some implementations, labeling the plurality of blocks as the bad blocks includes setting, by the peripheral circuit, a plurality of block labeling latches associated with the plurality of blocks to a bad block state, so that the plurality of blocks are labeled as the bad blocks.

In some implementations, relabeling the first and second blocks as the functioning blocks includes, for each block in the first and second blocks, setting, by the peripheral circuit, a block labeling latch associated with the corresponding block to a functioning block state, so that the corresponding block is relabeled as a functioning block.

In some implementations, selecting the first and second blocks relabeled as the functioning blocks based on the select-all-block signal includes: generating, by the peripheral circuit, first block-select signals having a block-select value to select the first and second blocks, respectively, based on the select-all-block signal; and generating, by the peripheral circuit, second block-select signals having a block-unselect value to unselect remaining blocks in the plurality of blocks, respectively, based on the select-all-block signal.

In some implementations, performing the first erase operation on the first and second blocks in the first period of time includes: applying an erase voltage to erase the first and second blocks in the first period of time while the first and second blocks are being selected; and applying a verify voltage to verify the erasing of the first and second blocks in the first period of time.

In some implementations, applying the erase voltage to erase the first and second blocks in the first period of time includes: applying an erase word line voltage to word lines coupled to the first block and word lines coupled to the second block in the first period of time while the first and second blocks are being selected; and applying the erase voltage to a common source line coupled to the first and second blocks to erase the first and second blocks in the first period of time while the first and second blocks are being selected.

In some implementations, applying the verify voltage to verify the erasing of the first and second blocks in the first period of time includes applying a verify voltage to word lines coupled to the first block and word lines coupled to the second block to verify the erasing of the first and second blocks in the first period of time while the first and second blocks are being selected.

In some implementations, applying the verify voltage to verify the erasing of the first and second blocks in the first period of time includes: selecting the first block and unselecting the second block; applying the verify voltage to word lines coupled to the first block to verify the erasing of the first block; unselecting the first block and selecting the second block; and applying the verify voltage to word lines coupled to the second block to verify the erasing of the second block.

In another aspect, a memory device is disclosed. The memory device includes a memory cell array and a peripheral circuit coupled to the memory cell array. The memory cell array includes a plurality of blocks including a first block, a second block, and a third block located between the first and second blocks in a plane of the memory device. The peripheral circuit is configured to select the first and second blocks from the plurality of blocks. The third block is unselected while the first and second blocks are being selected. The peripheral circuit is further configured to perform a first erase operation on the first and second blocks in the first period of time.

In some implementations, the peripheral circuit is further configured to select the third block from the memory device, and perform a second erase operation on the third block in a second period of time that is different from the first period of time.

In some implementations, the peripheral circuit includes a plurality of block select circuits corresponding to the plurality of blocks, respectively. The peripheral circuit further includes control logic configured to control an operation of the plurality of block select circuits.

In some implementations, the plurality of block select circuits include a plurality of block address latches, respectively. To select the first and second blocks from the plurality of blocks, the peripheral circuit is further configured to unselect the plurality of blocks. For each block in the first and second blocks, the peripheral circuit is further configured to: send, by the control logic, a block address of the corresponding block to a block select circuit associated with the corresponding block; and generate, by the block select circuit, a block-select signal having a block-select value to select the corresponding block responsive to receiving the block address of the corresponding block. The block-select signal is stored in a block address latch of the block select circuit.

In some implementations, to unselect the plurality of blocks, the peripheral circuit is further configured to: generate and send, by the control logic, a reset signal to the plurality of block select circuits, respectively; and reset, by the plurality of block select circuits, the plurality of block address latches in the plurality of block select circuits to an unselect state, respectively, responsive to receiving the reset signal, so that the plurality of blocks are unselected.

In some implementations, the plurality of block select circuits further include a plurality of block labeling latches, respectively. To generate the block-select signal, the block select circuit is configured to, responsive to receiving the block address of the corresponding block and a state of a block labeling latch in the block select circuit indicating that the corresponding block is a functioning block, generate the block-select signal having the block-select value.

In some implementations, the plurality of block select circuits include a plurality of block labeling latches, respectively. To select the first and second blocks from the plurality of blocks, the peripheral circuit is further configured to: label the plurality of blocks as bad blocks; relabel the first and second blocks as functioning blocks; and select the first and second blocks relabeled as the functioning blocks based on a select-all-block signal.

In some implementations, to label the plurality of blocks as the bad blocks, the peripheral circuit is further configured to: generate and send, by the control logic, a bad-block setting signal to the plurality of block select circuits, respectively; and set, by the plurality of block select circuits, the plurality of block labeling latches to a bad block state, respectively, responsive to receiving the bad-block setting signal, so that the plurality of blocks are labeled as the bad blocks.

In some implementations, to relabel the first and second blocks as the functioning blocks, the peripheral circuit is further configured to: for each block in the first and second blocks, generate and send, by the control logic, a functioning-block setting signal to a block select circuit associated with the corresponding block; and set, by the block select circuit, a block labeling latch in the block select circuit to a functioning block state, so that the corresponding block is relabeled as a functioning block.

In some implementations, to select the first and second blocks relabeled as the functioning blocks based on the select-all-block signal, the peripheral circuit is further configured to: generate and send, by the control logic, the select-all-block signal to the plurality of block select circuits; generate, by first block select circuits corresponding to the first and second blocks, first block-select signals having a block-select value to select the first and second blocks, respectively, responsive to receiving the select-all-block signal; and generate, by second block select circuits corresponding to remaining blocks in the plurality of blocks, second block-select signals having a block-unselect value to unselect the remaining blocks, respectively, responsive to receiving the select-all-block signal.

In some implementations, to perform the first erase operation on the first and second blocks in the first period of time, the peripheral circuit is further configured to: apply an erase voltage to erase the first and second blocks in the first period of time while the first and second blocks are being selected; and apply a verify voltage to verify the erasing of the first and second blocks in the first period of time.

In some implementations, to apply the erase voltage to erase the first and second blocks in the first period of time, the peripheral circuit is further configured to: apply an erase word line voltage to word lines coupled to the first block and word lines coupled to the second block in the first period of time while the first and second blocks are being selected; and apply the erase voltage to a common source line coupled to the first and second blocks to erase the first and second blocks in the first period of time while the first and second blocks are being selected.

In some implementations, to apply the verify voltage to verify the erasing of the first and second blocks in the first period of time, the peripheral circuit is further configured to: apply a verify voltage to word lines coupled to the first block and word lines coupled to the second block to verify the erasing of the first and second blocks in the first period of time while the first and second blocks are being selected.

In some implementations, to apply the verify voltage to verify the erasing of the first and second blocks in the first period of time, the peripheral circuit is further configured to: select the first block and unselect the second block; apply the verify voltage to word lines coupled to the first block to verify the erasing of the first block; unselect the first block and select the second block; and apply the verify voltage to word lines coupled to the second block to verify the erasing of the second block.

In still another aspect, a system is disclosed. The system includes a memory device and a memory controller coupled to the memory device and configured to control an operation of the memory device. The memory device includes a memory cell array and a peripheral circuit coupled to the memory cell array. The memory cell array includes a plurality of blocks including a first block, a second block, and a third block located between the first and second blocks in a plane of the memory device. The peripheral circuit is configured to select the first and second blocks from the plurality of blocks. The third block is unselected while the first and second blocks are being selected. The peripheral circuit is further configured to perform a first erase operation on the first and second blocks in the first period of time.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a block diagram of a system having a memory device, according to some aspects of the present disclosure.

FIG. 2A illustrates a diagram of a memory card having a memory device, according to some aspects of the present disclosure.

FIG. 2B illustrates a diagram of a solid-state drive (SSD) having a memory device, according to some aspects of the present disclosure.

FIG. 3 illustrates another block diagram of a system having a memory device, according to some aspects of the present disclosure.

FIG. 4 illustrates a schematic diagram of a memory device including peripheral circuits, according to some aspects of the present disclosure.

FIG. 5A illustrates a block diagram of a memory device including a memory cell array and peripheral circuits, according to some aspects of the present disclosure.

FIG. 5B illustrates a block diagram of a row decoder/word line driver including a plurality of block circuits coupled to a plurality of blocks, respectively, according to some aspects of the present disclosure.

FIG. 5C illustrates example connections between a block select circuit and a string driver in a block circuit, according to some aspects of the present disclosure.

FIG. 6 illustrates a circuit diagram of a block select circuit, according to some examples of the present disclosure.

FIG. 7A illustrates a circuit diagram of a block select circuit, according to some aspects of the present disclosure.

FIG. 7B illustrates another circuit diagram of a block select circuit, according to some aspects of the present disclosure.

FIG. 7C illustrates still another circuit diagram of a block select circuit, according to some aspects of the present disclosure.

FIG. 8 illustrates a flowchart of a method for operating a memory device, according to some examples of the present disclosure.

FIG. 9 illustrates a plurality of blocks included in a memory device, according to some aspects of the present disclosure.

FIG. 10 illustrates a process of operating a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

In some application scenarios, multiple blocks of a memory device may need to be erased before writing data into the memory device. The multiple blocks may be selected and erased one by one. Since the multiple blocks are erased in turn and the erasing of each block may take hundreds of microseconds (µs), it may take a long time to finish the erasing of the multiple blocks. When an odd-even-division erasing method is applied to erase the blocks, the total erasing time of the multiple blocks may be even longer.

For example, generally, a block can be selected and erased as a whole by applying an erase word line voltage (e.g., 0 V) to word lines of the block and applying an erase voltage to a common source line coupled to the block. However, when the odd-even-division erasing method is applied, the erasing of the block is divided into a first erasing of odd layers and a second erasing of even layers. Here, a layer of the block may refer to a row of memory cells coupled to the same word line. Specifically, in the first erasing of odd layers, the erase word line voltage (e.g., 0V) can be applied to word lines coupled to the odd layers of the block, and the erase voltage can be applied to the common source line coupled to the block, so that the odd layers are selected and erased. Meanwhile, an unselect word line voltage (e.g., 20 V) can be applied to word lines coupled to the even layers of the block, so that the even layers are unselected and not erased. Subsequently, in the second erasing of even layers, the erase word line voltage (e.g., 0V) can be applied to the word lines coupled to the even layers of the block, and the erase voltage can be applied to the common source line coupled to the block, so that the even layers are selected and erased. Meanwhile, the unselect word line voltage (e.g., 20 V) can be applied to the word lines coupled to the odd layers of the block, so that the odd layers are unselected. Because the erasing of the block is divided into the first erasing of odd layers and the second erasing of even layers, the erasing time of the block may be twice that when the entire block is erased as a whole.

In a further example, assuming that three discontinuous blocks (e.g., three random blocks that are not adjacent to one another) in a plane of the memory device may need to be erased before performing a program operation. The time to erase a block is denoted as t_{ERS}. If the three blocks are selected and erased one by one, the total erasing time of the three blocks is 3* t_{ERS}. When the odd-even-division erasing method is applied to erase each of the three blocks, the total erasing time of the three blocks may further increase. However, if the three blocks can be erased at once (e.g., the three blocks are selected and erased simultaneously), the total erasing time can be greatly reduced. Therefore, it would be desirable to select and erase multiple discontinuous blocks at the same time.

To address one or more of the aforementioned issues, the present disclosure introduces a flexible multi-block erasing scheme which can select and erase multiple blocks in a same period of time so that the total erasing time of the multiple blocks can be greatly reduced. The multiple blocks can be any blocks in a plane of a memory device, which is not limited herein. For example, the flexible multi-block erasing scheme disclosed herein can select and erase multiple discontinuous blocks from a plane of the memory device in the same period of time.

In a further example, multiple blocks from a plane of the memory device can be selected, and an erase voltage can be applied to a common source line of the multiple blocks to erase the multiple blocks simultaneously. Subsequently, a verify voltage may be applied to verify the erasing of the multiple blocks simultaneously or one block by one block. As a result, the erasing time of the multiple blocks can be reduced significantly. The performance of the memory device can be improved.

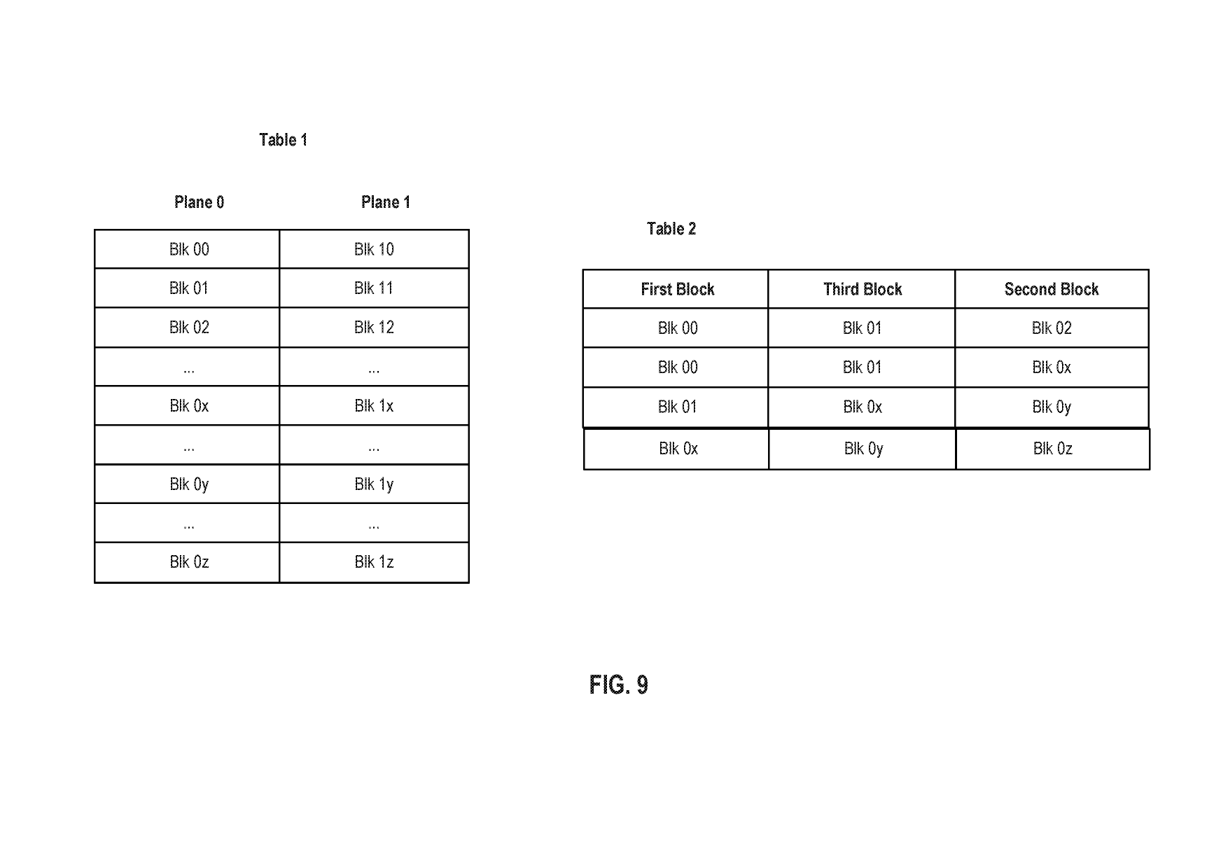

Consistent with some aspects of the present disclosure, if a first block and a second block from the same plane of the memory device is not adjacent to each other (e.g., there is at least a third block located between the first block and the second block), then the first block and the second block may be referred to as two discontinuous blocks. With respect to three or more blocks, if at least one of the blocks is not adjacent to any one of the remaining blocks, the three or more blocks may also be referred to as discontinuous blocks. For example, if a first block is adjacent to a second block, the second block is also adjacent to a third block, and a fourth block is not adjacent to any one of the first, second, and third blocks, then the first, second, third and fourth blocks may also be referred to as discontinuous blocks. Examples of discontinuous blocks are illustrated below in FIG. 9.

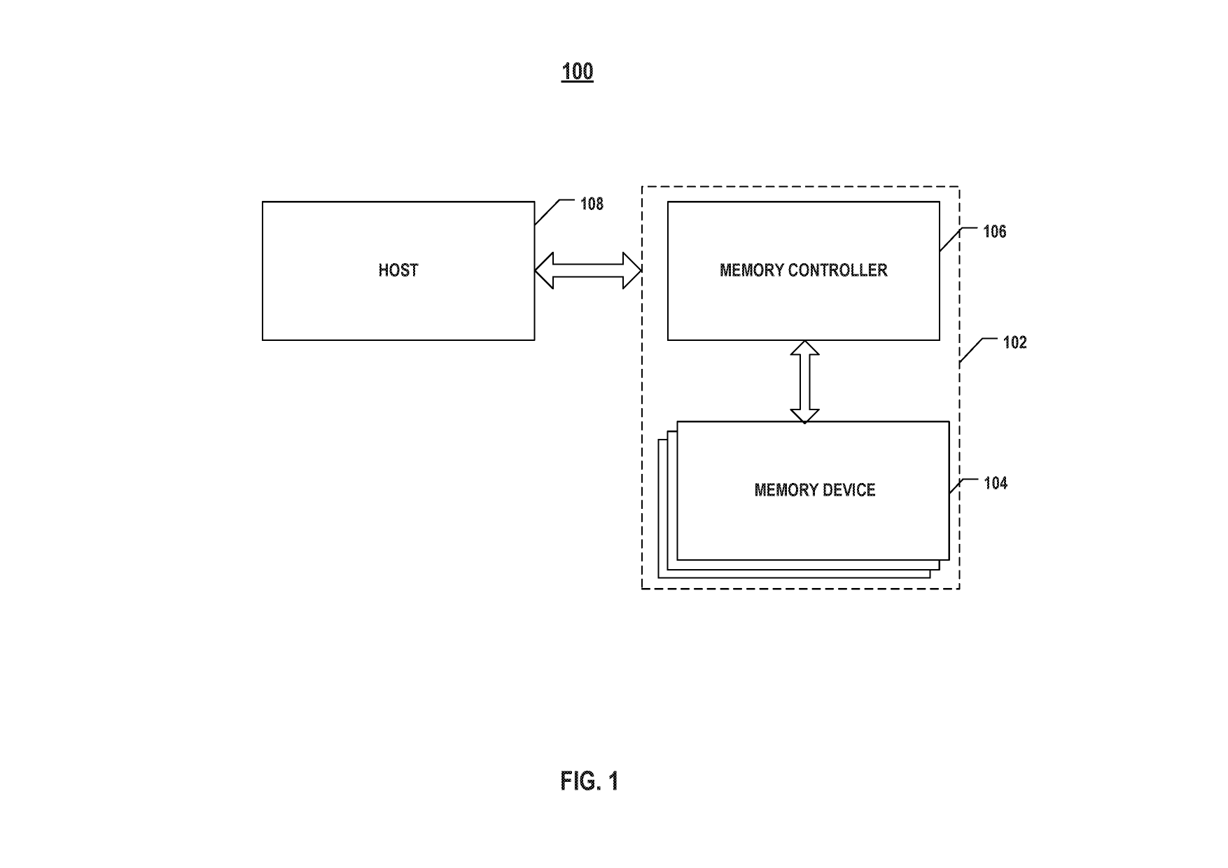

FIG. 1 illustrates a block diagram of a system 100 including a memory system 102, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data (a.k.a. user data or host data) to or from memory system 102. Memory system 102 can be a storage product integrating memory controller 106 and one or more memory devices 104, such as an SSD.

Memory devices 104 can be any memory devices disclosed in the present disclosure, including non-volatile memory devices, such as NAND Flash memory devices. In some implementations, memory device 104 also includes one or more volatile memory devices, such as dynamic random-access memory (DRAM) devices or static random-access memory (SRAM) devices.

Memory controller 106 is operatively coupled to memory devices 104 and host 108 and is configured to control memory devices 104, according to some implementations. Memory controller 106 can manage the data stored in memory devices 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment with SSDs or embedded multimedia card (eMMCs) used as data storage for mobile devices, such as smartphones, tablets, laptop computers, etc., and enterprise storage arrays. Memory controller 106 can be configured to control operations of memory devices 104, such as read, program/write, and/or erase operations. Memory controller 106 can also be configured to manage various functions with respect to the data stored or to be stored in memory devices 104 including, but not limited to bad-block management, garbage collection, logical-to-physical (L2P) address conversion, wear-leveling, etc. In some implementations, memory controller 106 is further configured to process error correction codes (ECCs) with respect to the data read from or written to memory devices 104. Any other suitable functions may be performed by memory controller 106 as well, for example, formatting memory devices 104. Memory controller 106 can communicate with an external device (e.g., host 108) according to a particular communication protocol. For example, memory controller 106 may communicate with the external device through at least one of various interface protocols, such as a non-volatile memory express (NVMe) protocol, an NVMe-over-fabrics (NVMe-oF) protocol, a PCI-express (PCI-E) protocol, a universal serial bus (USB) protocol, a multimedia card (MMC) protocol, a peripheral component interconnection (PCI) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

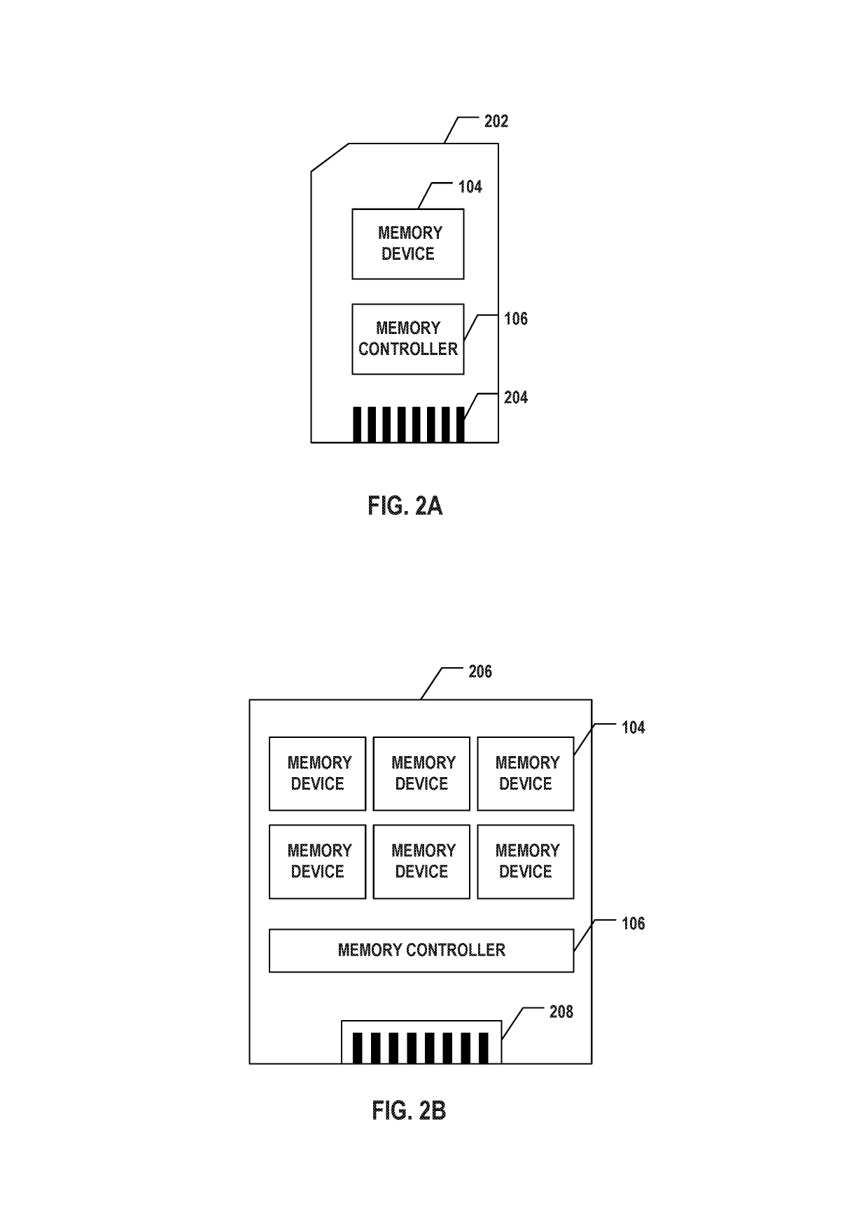

Memory controller 106 and one or more memory devices 104 can be integrated into various types of storage devices, for example, being included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 1). In another example as shown in FIG. 2B, memory controller 106 and multiple memory devices 104 may be integrated into an SSD 206. SSD 206 can further include an SSD connector 208 coupling SSD 206 with a host (e.g., host 108 in FIG. 1). In some implementations, the storage capacity and/or the operation speed of SSD 206 is greater than those of memory card 202. In some implementations, memory system 102 is implemented as an SSD 206 that includes both non-volatile memory devices and volatile memory devices as memory devices 104, such as an enterprise SSD.

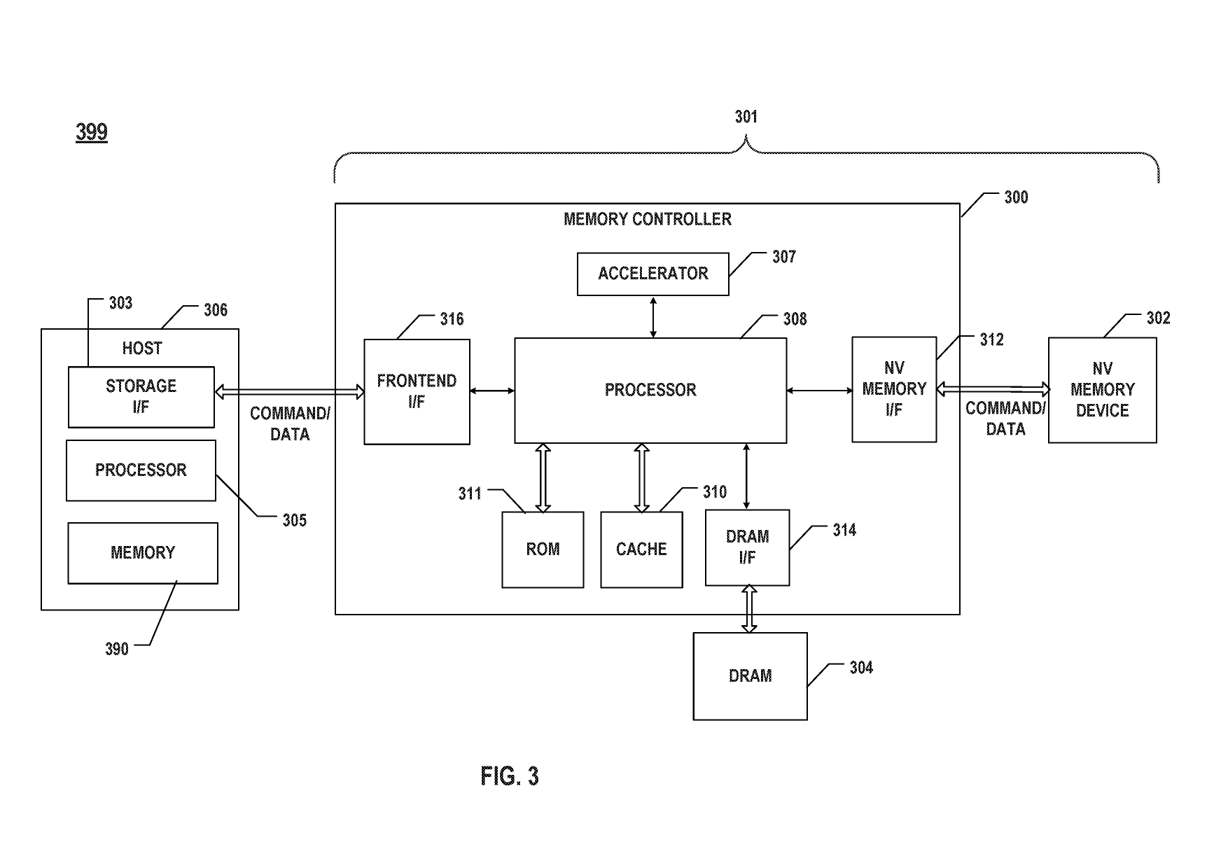

FIG. 3 illustrates another block diagram of a system 399 having a memory device, according to some aspects of the present disclosure. System 399 may be an example of system 100 in FIG. 1. System 399 may include a host 306 (e.g., an example of host 108 in FIG. 1) and a memory system 301 (e.g., an example of memory system 102 in FIG. 1). Memory system 301 may include a memory controller 300 (e.g., an example of memory controller 106 in FIG. 1) and a non-volatile memory device 302 (e.g., an example of memory device 104 in FIG. 1).

As shown in FIG. 3, memory controller 300 can include a processor 308, an accelerator 307 (e.g., a hardware accelerator), a cache 310, and a read-only memory (ROM) 311. In some implementations, processor 308 is implemented by microprocessors (e.g., digital signal processors (DSPs)) or microcontrollers (a.k.a. microcontroller units (MCUs)) that execute firmware and/or software modules to perform the various functions described herein. The various firmware modules in memory controller 300 described herein can be implemented as firmware codes or instructions stored in ROM 311 and executed by processor 308. In some implementations, processor 308 includes one or more hardware circuits, for example, fixed logic units such as a logic gate, a multiplexer, a flip-flop, a state machine, field-programmable gate arrays (FPGAs), programmable logic devices (PLDs). For example, the hardware circuits may include dedicated circuits performing a given logic function that is known at the time of device manufacture, such as application-specific integrated circuits (ASICs).

As shown in FIG. 3, memory controller 300 can also include various input/output (I/O) interfaces (I/F), such as a non-volatile memory interface 312, a DRAM interface 314, and a frontend interface 316 operatively coupled to non-volatile memory device 302 (e.g., flash memory), DRAM 304 (e.g., an example of volatile memory devices), and host 306, respectively. Non-volatile memory interface 312, DRAM interface 314, and frontend interface 316 can be configured to transfer data, command, clock, or any suitable signals between processor 308 and non-volatile memory device 302, DRAM 304, and host 306, respectively. Non-volatile memory interface 312, DRAM interface 314, and frontend interface 316 can implement any suitable communication protocols facilitating data transfer, communication, and management, such as the NVMe protocol and PCI-E protocol, double data rate (DDR) protocol, to name a few.

As described above, both cache 310 and DRAM 304 may be considered volatile memory devices that can be controlled and accessed by memory controller 300 in a memory system. In some implementations, a cache can be implemented as part of volatile memory devices, for example, by an SRAM and/or DRAM 304. It is understood that although FIG. 3 shows that cache 310 is within memory controller 300, and DRAM 304 is outside of memory controller 300. In some examples, both cache 310 and DRAM 304 may be within memory controller 300 or outside of memory controller 300.

In some implementations, DRAM 304 and DRAM I/F 314 may be optional components of memory system 301. That is, memory system 301 may not include DRAM 304 and DRAM I/F 314 in some examples. For example, memory system 301 may include a UFS device that does not have any DRAM therein.

Host 306 may include a storage interface (I/F) 303, a processor 305, and a memory 390. Storage interface 303 may be operatively coupled to frontend interface 316 of memory controller 300. Storage interface 303 may be configured to transfer data, command, or any suitable signals between host 306 and memory controller 300. Storage interface 303 can implement any suitable communication protocols facilitating data transfer, communication, and management, such as the NVMe protocol, the PCI-E protocol, SCSI, to name a few. Processor 305 may have a structure like that of processor 308, and a similar description will not be repeated herein.

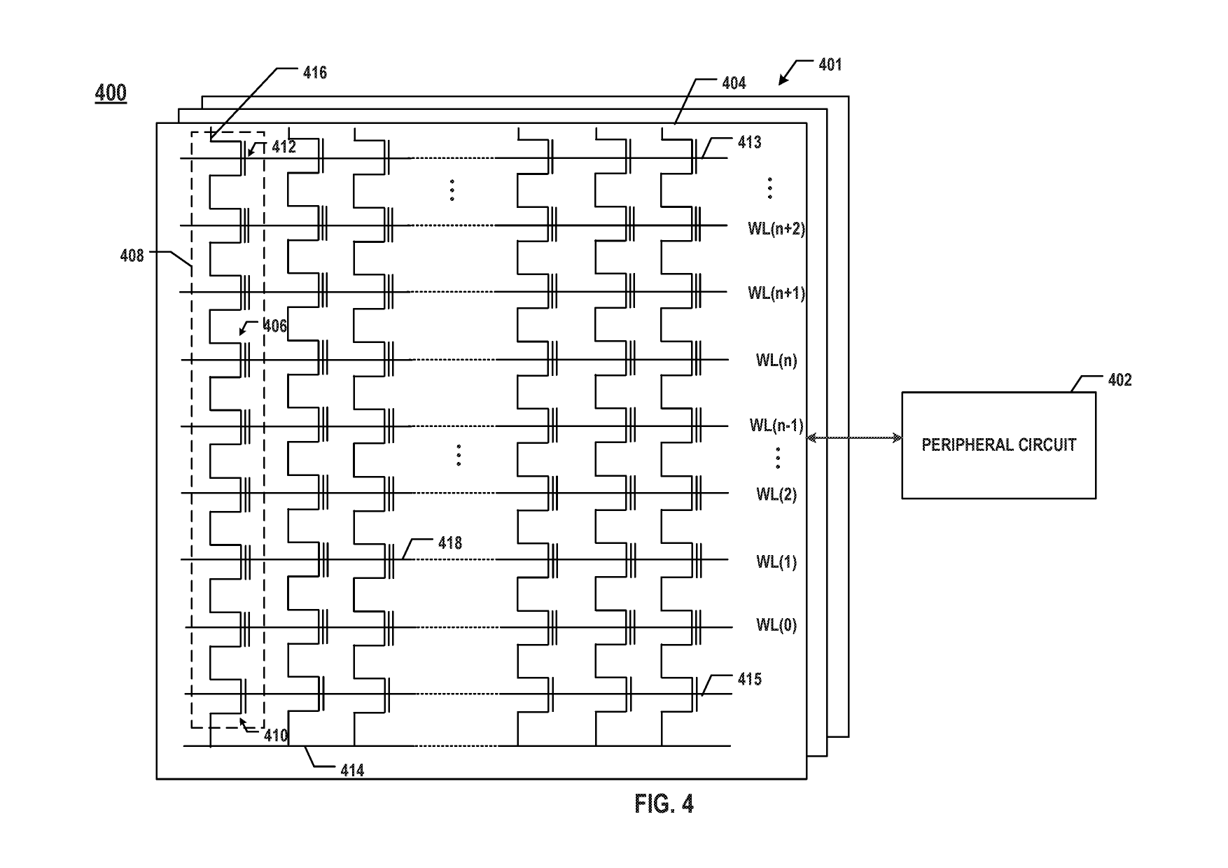

FIG. 4 illustrates a schematic diagram of a memory device 400 including peripheral circuits 402, according to some aspects of the present disclosure. Memory device 400 can be an example of memory device 104 in FIG. 1 or non-volatile memory device 302 in FIG. 3. Memory device 400 can include a memory cell array 401 and peripheral circuits 402 coupled to memory cell array 401. Memory cell array 401 can be a NAND Flash memory cell array in which memory cells 406 are provided in an array of NAND memory strings 408 each extending vertically above a substrate (not shown). In some implementations, each NAND memory string 408 includes a plurality of memory cells 406 coupled in series and stacked vertically. Each memory cell 406 can hold a continuous, analog value, such as an electrical voltage or charge, that depends on the number of electrons trapped within a region of memory cell 406. Each memory cell 406 can be either a floating gate type of memory cell including a floating-gate transistor or a charge trap type of memory cell including a charge-trap transistor.

In some implementations, each memory cell 406 is a single-level cell (SLC) that has two possible memory states and thus, can store one bit of data. For example, the first memory state “0” can correspond to a first range of voltages, and the second memory state “1” can correspond to a second range of voltages. In some implementations, each memory cell 406 is a multi-level cell (MLC) that is capable of storing more than a single bit of data in more than four memory states. For example, the MLC can store two bits per cell, three bits per cell (also known as TLC), or four bits per cell (also known as QLC). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 4, each NAND memory string 408 can also include a source select gate (SSG) transistor 410 at its source end and a drain select gate (DSG) transistor 412 at its drain end. SSG transistor 410 and DSG transistor 412 can be configured to activate select NAND memory strings 408 (columns of the array) during read and program operations. In some implementations, the sources of NAND memory strings 408 in the same block 404 are coupled through a same source line (SL) 414, e.g., a common SL. In other words, all NAND memory strings 408 in the same block 404 have an array common source (ACS), according to some implementations. The drain of each NAND memory string 408 is coupled to a respective bit line 416 from which data can be read or written via an output bus (not shown), according to some implementations. In some implementations, each NAND memory string 408 is configured to be selected or deselected by applying a DSG select voltage or a DSG unselect voltage to the gate of respective DSG transistor 412 through one or more DSG lines 413 and/or by applying an SSG select voltage or an SSG unselect voltage to the gate of respective SSG transistor 410 through one or more SSG lines 415.

As shown in FIG. 4, NAND memory strings 408 can be organized into multiple blocks 404, each of which can have a common source line 414, e.g., coupled to an ACS. In some implementations, each block 404 is the basic data unit for erase operations, i.e., all memory cells 406 on the same block 404 are erased at the same time. To erase memory cells 406 in a select block 404, source lines 414 coupled to select block 404 as well as unselect blocks 404 in the same plane as select block 404 can be biased with an erase voltage (Vers), such as a high positive voltage (e.g., 20 V or more). Memory cells 406 of adjacent NAND memory strings 408 can be coupled through word lines 418 that select which row of memory cells 406 is affected by read and program operations. Each word line 418 can include a plurality of control gates (gate electrodes) at each memory cell 406 coupled to word line 418 and a gate line coupling the control gates. With reference to FIG. 4, a plurality of word lines WL(0), WL(1), WL(2), ..., WL(n-1), WL(n), WL(n+1), and WL(n+2) are illustrated, with n being a positive integer.

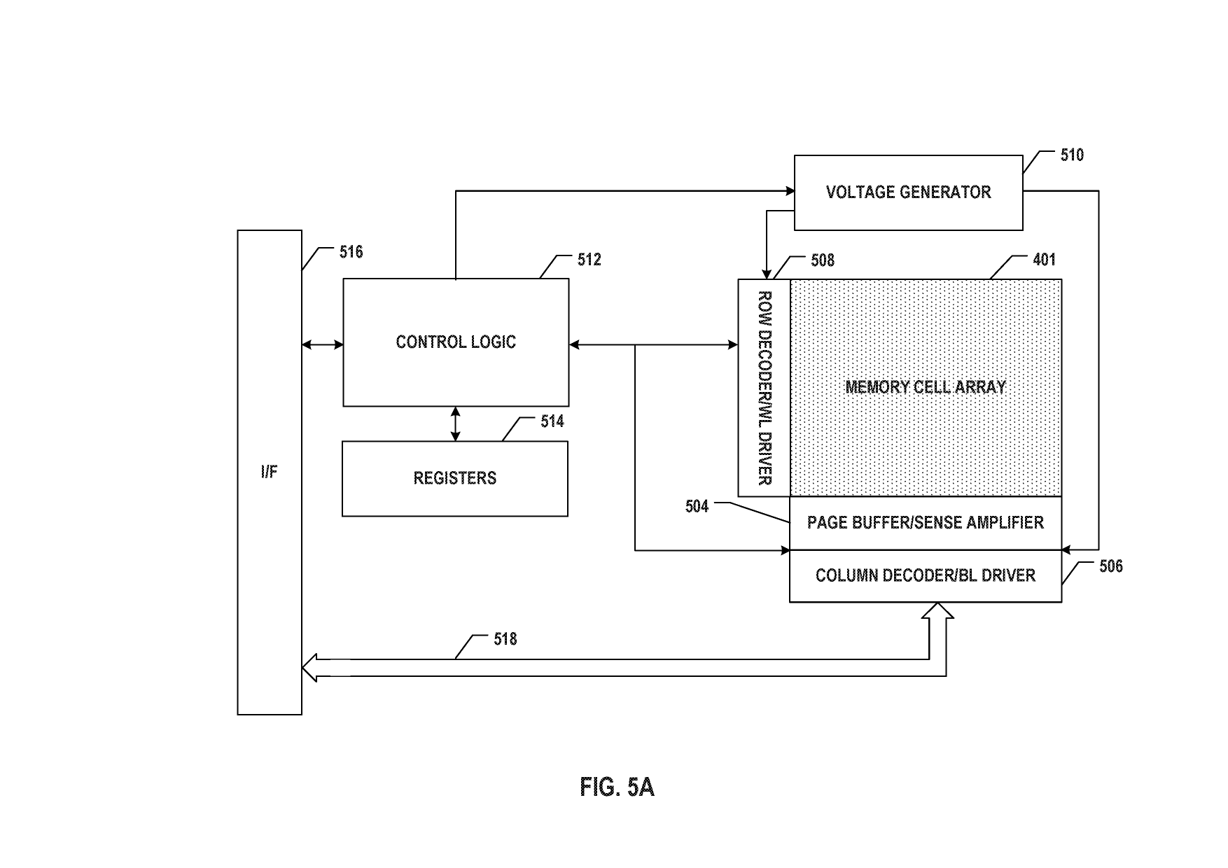

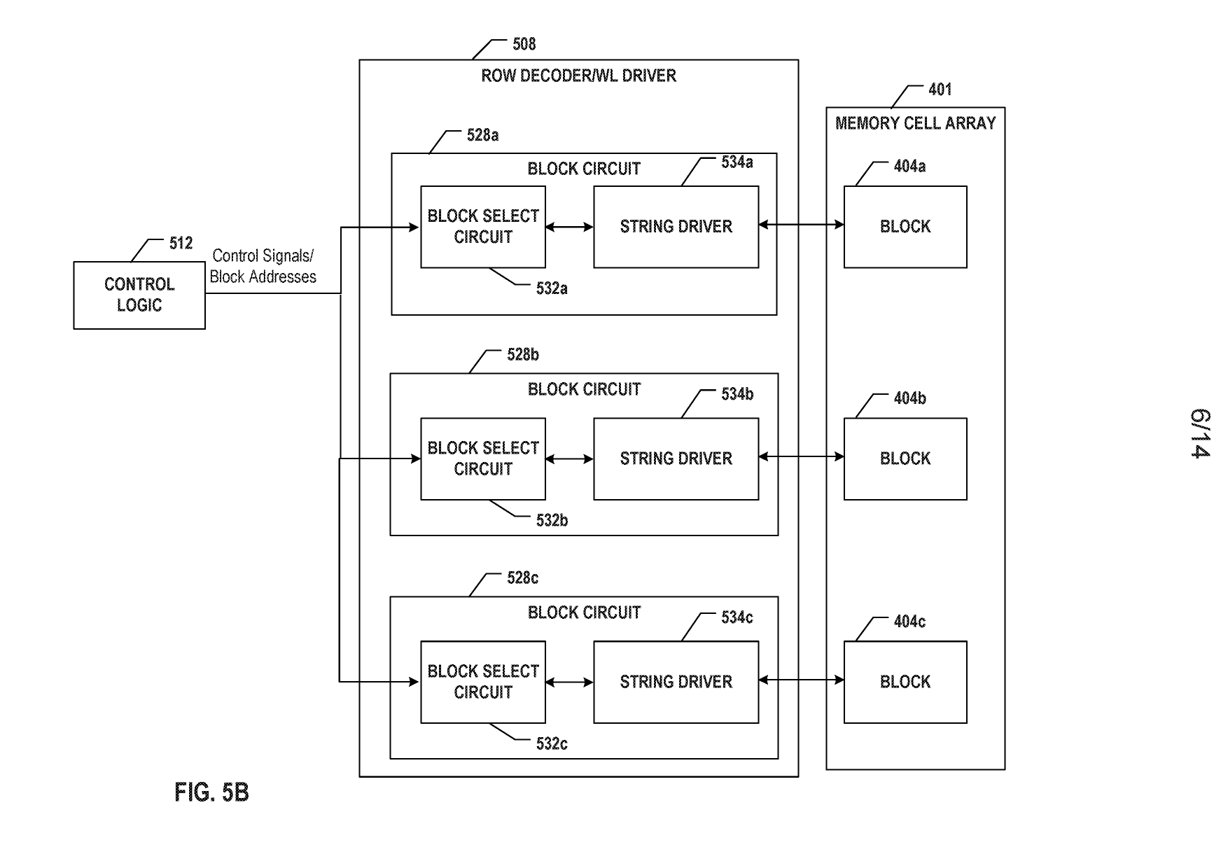

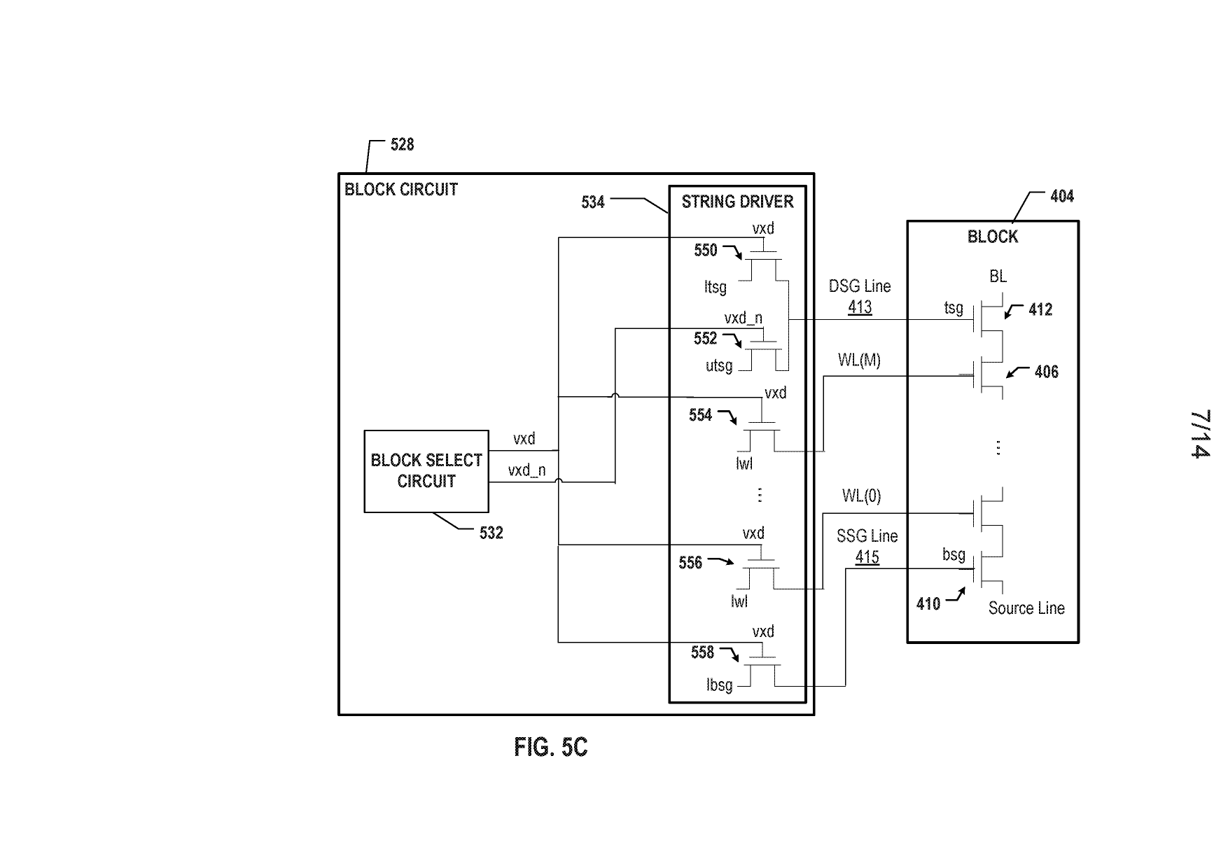

Peripheral circuits 402 can be coupled to memory cell array 401 through bit lines 416, word lines 418, source lines 414, SSG lines 415, and DSG lines 413. Peripheral circuits 402 can include any suitable analog, digital, and mixed-signal circuits for facilitating the operations of memory cell array 401 by applying and sensing voltage signals and/or current signals to and from each target memory cell 406 through bit lines 416, word lines 418, source lines 414, SSG lines 415, and DSG lines 413. Peripheral circuits 402 can include various types of peripheral circuits formed using metal-oxide-semiconductor (MOS) technologies. For example, FIG. 5A illustrates some peripheral circuits including a page buffer/sense amplifier 504, a column decoder/bit line driver 506, a row decoder/word line driver 508, a voltage generator 510, control logic 512, registers 514, an interface 516, and a data bus 518. It is understood that in some examples, additional peripheral circuits not shown in FIG. 5A may be included as well.

Page buffer/sense amplifier 504 can be configured to read and program (write) data from and to memory cell array 401 according to the control signals from control logic 512. In one example, page buffer/sense amplifier 504 may store program data (write data) to be programmed. In another example, page buffer/sense amplifier 504 may verify programmed target memory cells 406 in each program/verify loop (cycle) in a program operation to ensure that the data has been properly programmed into memory cells 406 coupled to select word lines 418. In still another example, page buffer/sense amplifier 504 may also sense the low power signals from bit line 416 that represents a data bit stored in memory cell 406 and amplify the small voltage swing to recognizable logic levels in a read operation. In program operations, page buffer/sense amplifier 504 can include storage modules (e.g., latches, caches, registers, etc.) for temporarily storing a set of N-bits data (e.g., in the form of gray codes) received from data bus 518 and providing the set of N-bits data to a corresponding target memory cell 406 through the corresponding bit line 416 in each program pass of a multi-pass program operation.

Column decoder/bit line driver 506 can be configured to be controlled by control logic 512 and select one or more NAND memory strings 408 by applying bit line voltages generated from voltage generator 510. Row decoder/word line driver 508 can be configured to be controlled by control logic 512 and select/deselect blocks 404 of memory cell array 401 and select/deselect word lines 418 of block 404. Row decoder/word line driver 508 can be further configured to drive word lines 418 using word line voltages generated from voltage generator 510. In some implementations, row decoder/word line driver 508 can also select/deselect and drive SSG lines 415 and DSG lines 413 as well. Voltage generator 510 can be configured to be controlled by control logic 512 and generate the word line voltages (e.g., read voltage, program voltage, channel pass voltage, local voltage, verify voltage, etc.), bit line voltages, and source line voltages to be supplied to memory cell array 401.

Control logic 512 can be coupled to each peripheral circuit described above and configured to control the operations of each peripheral circuit. Registers 514 can be coupled to control logic 512 and include status registers, command registers, and address registers for storing status information, command operation codes (OP codes), and command addresses for controlling the operations of each peripheral circuit. Interface 516 can be coupled to control logic 512 and act as a control buffer to buffer and relay control commands received from a host (e.g., 108 in FIG. 1) to control logic 512 and status information received from control logic 512 to the host. Interface 516 can also be coupled to column decoder/bit line driver 506 via data bus 518 and act as a data input/output (I/O) interface and a data buffer to buffer and relay the data to and from memory cell array 401.

FIG. 5B illustrates a block diagram of row decoder/word line driver 508 of FIG. 5A, according to some aspects of the present disclosure. Row decoder/word line driver 508 may include a plurality of block circuits 528a, 528b, 528c coupled to a plurality of blocks 404a, 404b, 404c, respectively. Block circuit 528a may include a block select circuit 532a and a string driver 534a. Block circuit 528b may include a block select circuit 532b and a string driver 534b. Block circuit 528c may include a block select circuit 532c and a string driver 534c. Block circuits 528a, 528b, 528c may be referred to as block circuit 528 collectively or individually. Blocks 404a, 404b, 404c may also be referred to as block 404 collectively or individually. Block select circuits 532a, 532b, 532c may also be referred to as block select circuit 532 collectively or individually. String drivers 534a, 534b, 534c may also be referred to as string driver 534 collectively or individually.

Each block circuit 528 may be coupled to control logic 512 and receive control signals (e.g., a select-all-block signal or any other control signals disclosed herein) from control logic 512. Each block circuit 528 may also receive address signals (e.g., a block address associated with a block to be erased) from control logic 512. For example, control logic 512 may receive a block address associated with a block to be erased from a memory controller (e.g., memory controller 300) and forward the block address to each block circuit 528.

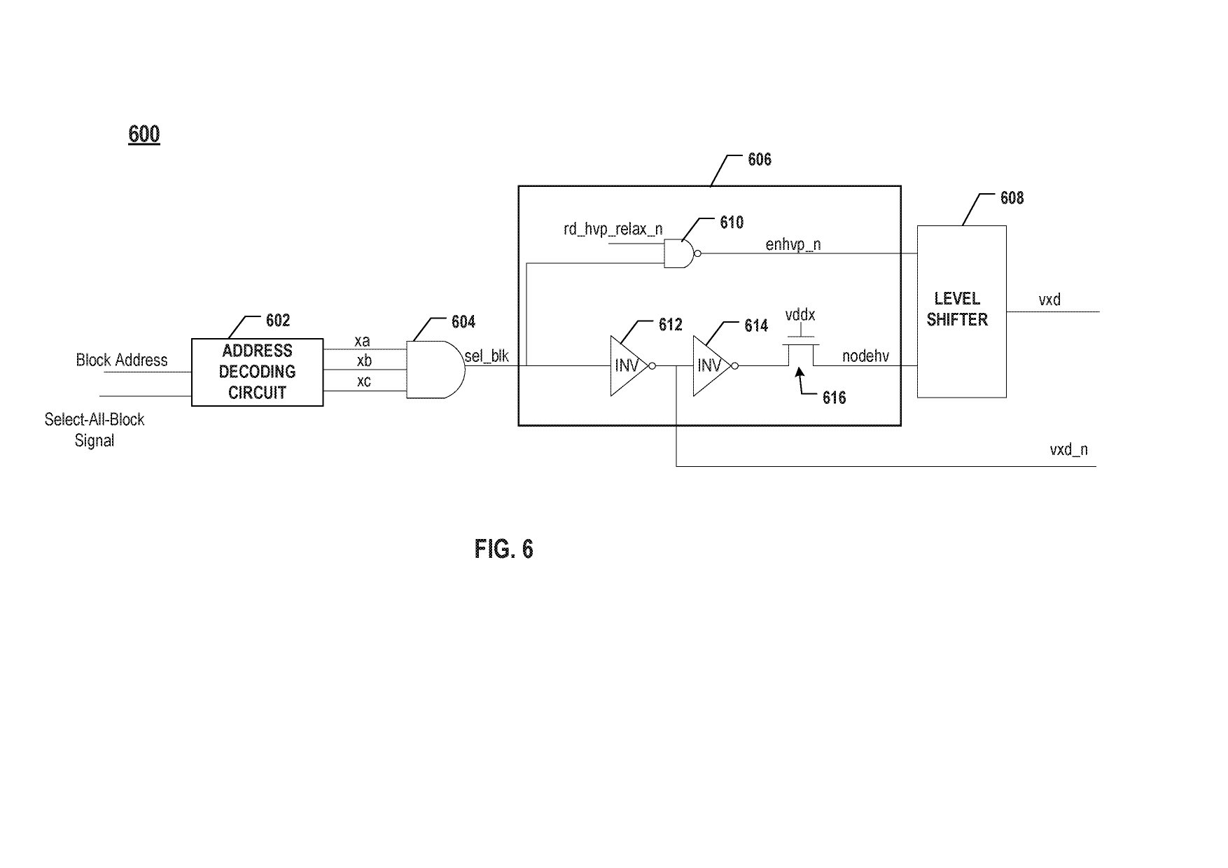

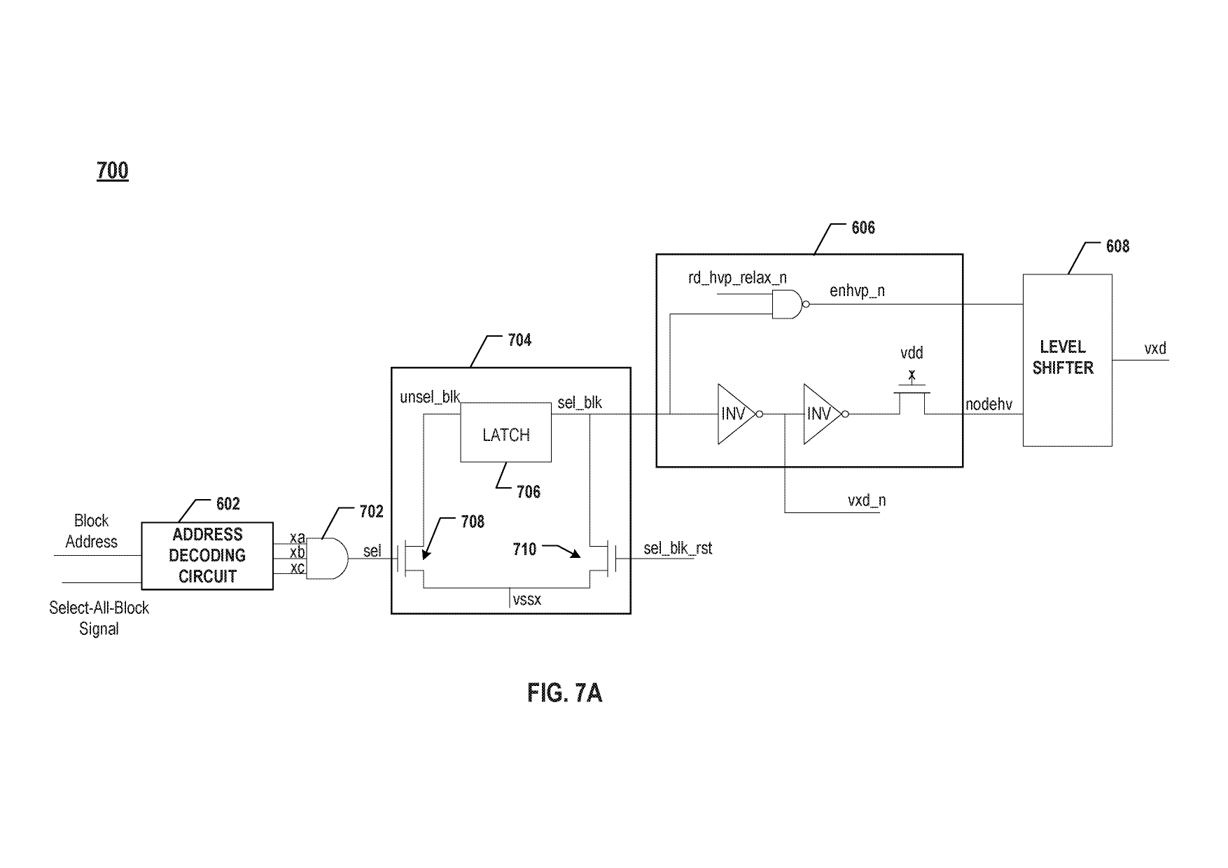

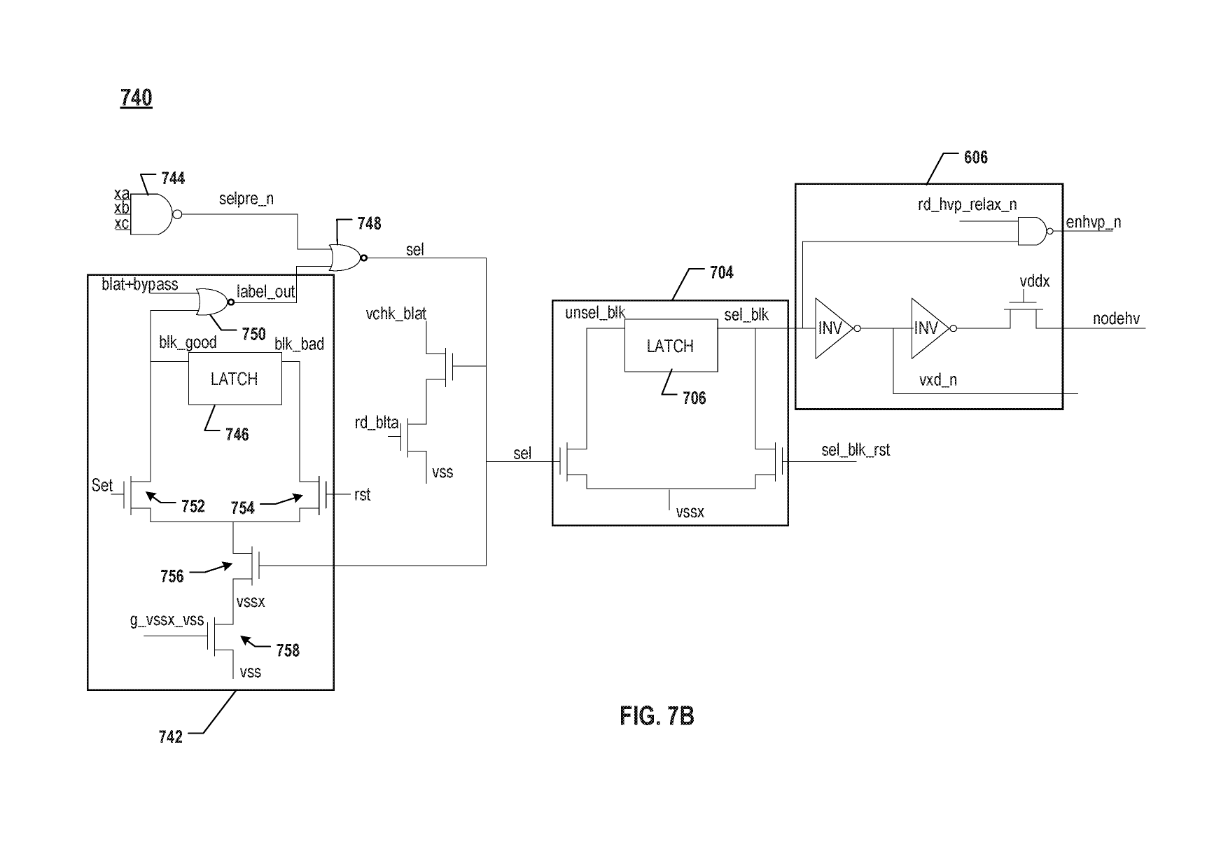

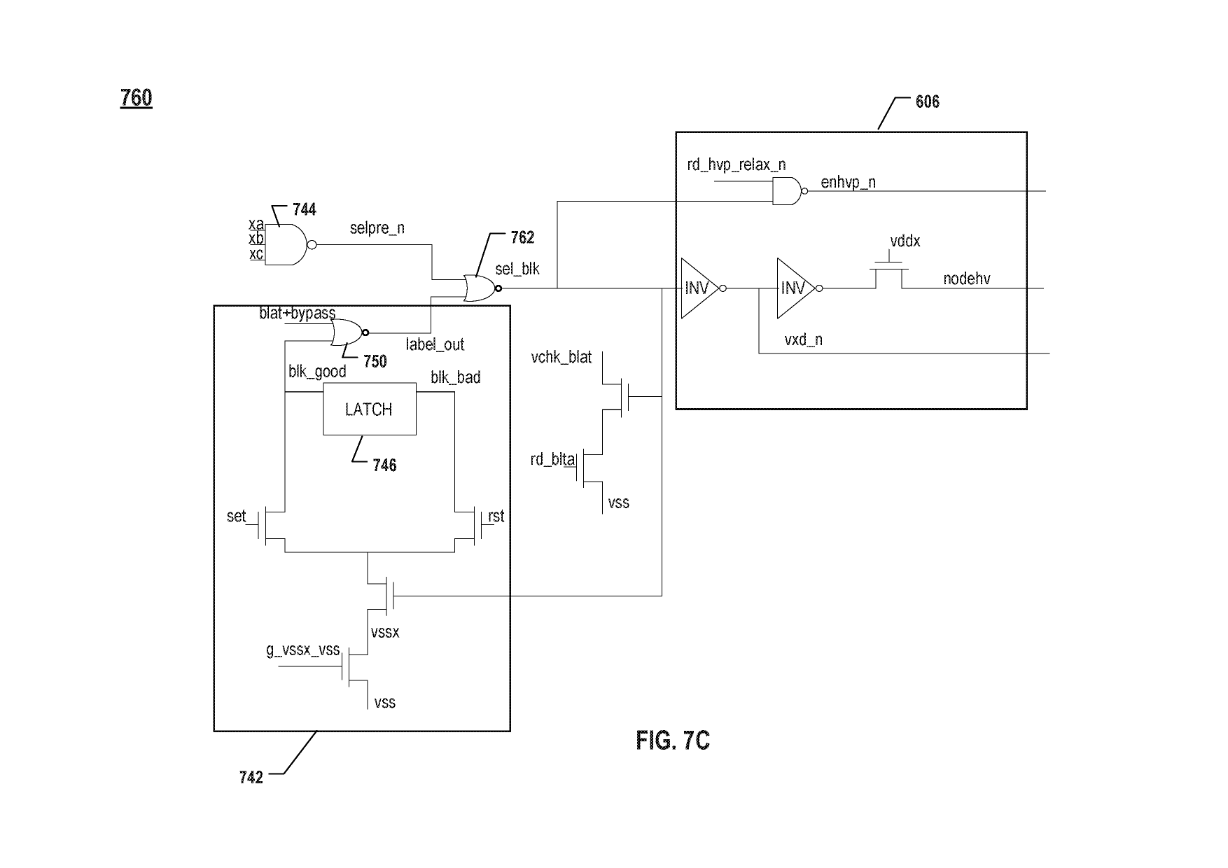

FIG. 5C illustrates example connections between block select circuit 532 and string driver 534 in each block circuit 528, according to some implementations of the present disclosure. Block select circuit 532 may receive a block address from control logic 512, and determine whether a block 404 corresponding to block circuit 528 is to be selected responsive to receiving the block address. If block 404 corresponding to block circuit 528 is to be selected, block select circuit 532 may generate and send a first control signal vxd having a switch-on voltage to string driver 534, causing string driver 534 to provide select signals to block 404 so that block 404 is selected. The select signals may include a DSG select voltage ltsg, an erase word line voltage lwl, an SSG select voltage lbsg, etc., as shown in FIG. 5C. Otherwise (if block 404 corresponding to block circuit 528 is not to be selected), block select circuit 532 may generate and send a second control signal vxd_n having a switch-on voltage to string driver 534, causing string driver 534 to generate unselect signals so that block 404 is unselected. The unselect signals may include a DSG unselect voltage utsg (shown in FIG. 5C), an unselect word line voltage, an SSG unselect voltage, etc. The first control signal vxd and the second control signal vxd_n are described below in more detail. Example implementations of block select circuit 532 are provided below with reference to FIGS. 6 and 7A-7C.

In FIG. 5C, a memory string coupled to a bit line (BL) is illustrated in block 404. For example, the memory string can be NAND memory string 408 of FIG. 4. A DSG transistor 412 and an SSG transistor 410, as well as a memory cell 406, of the memory string are also illustrated in block 404. It is contemplated that block 404 may include any number of memory strings, which is not limited herein.

String driver 534 may be coupled to block select circuit 532 and the memory string of block 404. String driver 534 may include a plurality of transistors such as 550, 552, 554, 556, and 558. With respect to transistor 550, a gate of transistor 550 may be coupled to block select circuit 532 and configured to receive the first control signal vxd. A source of transistor 550 may be coupled to voltage generator 510 of FIG. 5A and configured to receive a DSG select voltage ltsg, and a drain of transistor 550 may be coupled to DSG line 413 of the memory string. With respect to transistor 552, a gate of transistor 552 may be coupled to block select circuit 532 and configured to receive the second control signal vxd_n. A source of transistor 552 may be coupled to voltage generator 510 of FIG. 5A and configured to receive a DSG unselect voltage utsg, and a drain of transistor 552 may be coupled to DSG line 413 of the memory string. With respect to transistor 554, a gate of transistor 554 may be coupled to block select circuit 532 and configured to receive the first control signal vxd. A source of transistor 554 may be coupled to voltage generator 510 of FIG. 5A and configured to receive an erase word line select voltage lwl, and a drain of transistor 554 may be coupled to a word line WL(M) of the memory string, where M is a positive integer.

With respect to transistor 556, a gate of transistor 556 may be coupled to block select circuit 532 and configured to receive the first control signal vxd. A source of transistor 556 may be coupled to voltage generator 510 of FIG. 5A and configured to receive the erase word line select voltage lwl, and a drain of transistor 556 may be coupled to a word line WL(0) of the memory string. With respect to transistor 558, a gate of transistor 558 may be coupled to block select circuit 532 and configured to receive the first control signal vxd. A source of transistor 558 may be coupled to voltage generator 510 of FIG. 5A and configured to receive an SSG select voltage lbsg, and a drain of transistor 558 may be coupled to SSG line 415 of the memory string.

In some implementations, if block 404 corresponding to block circuit 528 is to be selected, the first control signal vxd may have a switch-on voltage, so that transistors 550, 554, 556, and 558 are switched on. The second control signal vxd_n may have a switch-off voltage, so that transistor 552 is switched off. Then, the DSG select voltage ltsg can be transmitted to DSG line 413 through transistor 550. The erase word line voltage lwl can be transmitted to the word line WL(M) and the word line WL(0) through transistor 554 and transistor 556, respectively. The SSG select voltage lbsg can be transmitted to SSG line 415 through transistor 558. As a result, the memory string of block 404 is selected. By performing similar operations, all the other memory strings in block 404 are selected so that the entire block 404 is selected.

In some implementations, if block 404 corresponding to block circuit 528 is not to be selected, the first control signal vxd may have a switch-off voltage, so that transistors 550, 554, 556, and 558 are switched off. The second control signal vxd_n may have a switch-on voltage, so that transistor 552 is switched on. Then, the DSG unselect voltage utsg can be transmitted to DSG line 413 through transistor 552. An unselect word line voltage can be transmitted from string driver 534 to the word line WL(M) and the word line WL(0), respectively. An SSG unselect voltage can be transmitted from string driver 534 to SSG line 415. As a result, the memory string of block 404 is unselected. By performing similar operations, all the other memory strings of block 404 can be unselected, and therefore, the entire block 404 is unselected.

FIG. 6 illustrates a circuit diagram of a block select circuit 600, according to some examples of the present disclosure. Block select circuit 600 can be an example implementation of block select circuit 532 of FIGS. 5B and 5C. Block select circuit 600 may include an address decoding circuit 602, an AND gate 604, a subcircuit 606, and a level shifter 608.

In some implementations, address decoding circuit 602 may be configured to receive a block address from control logic 512 and generate decoded signals xa, xb, and xc based on the block address. Address decoding circuit 602 may be coupled to AND gate 604 and provide the decoded signals xa, xb, and xc as inputs to AND gate 604. AND gate 604 may then generate a block-select signal sel_blk based on the decoded signals.

For example, if the block address received from control logic 512 is a block address of a block corresponding to block select circuit 600, indicating that the block corresponding to block select circuit 600 is to be selected, address decoding circuit 602 may generate the decoded signals each of which has a value of 1 (e.g., xa=1, xb=1, and xc=1). Then, AND gate 604 may generate and output the block-select signal sel_blk having a block-select value (e.g., sel_blk = 1). Alternatively, if the block address received from control logic 512 is not the block address of the block corresponding to block select circuit 600, indicating that the block corresponding to block select circuit 600 is not to be selected, address decoding circuit 602 may generate the decoded signals with at least one of the decoded signals having a value of 0 (e.g., xa=0, or xb=0, or xc=0). Then, AND gate 604 may generate and output the block-select signal sel_blk having a block-unselect value (e.g., sel_blk = 0).

In some implementations, address decoding circuit 602 may receive, from control logic 512, a select-all-block signal indicating that all blocks of the memory device are to be selected. Responsive to receiving the select-all-block signal, address decoding circuit 602 may generate the decoded signals, each of which has a value of 1 (e.g., xa=1, xb=1, and xc=1). Then, AND gate 604 may generate and output the block-select signal sel_blk having the block-select value (e.g., sel_blk = 1).

Subcircuit 606 may be coupled to AND gate 604 and receive the block-select signal sel_blk from AND gate 604. Subcircuit 606 may include an NAND gate 610, inverters 612 and 614, and a transistor 616. NAND gate 610 may receive the block-select signal sel_blk as a first input, and receive a signal rd_hvp_relax_n as a second input. NAND gate 610 may generate a signal enhvp_n based on the first input and the second input, and provide the signal enhvp_n to level shifter 608. Inverter 612 may receive the block-select signal as an input, and generate and output the second control signal vxd_n. Inverter 614 may receive the second control signal vxd_n outputted from inverter 612. An output end of inverter 614 is coupled to a source of transistor 616. A gate of transistor 616 is coupled to a signal vddx. A drain of transistor 616 is coupled to level shifter 608 and provides a signal nodehv to level shifter 608. Level shifter 608 may generate the first control signal vxd based on the signal enhvp_n from NAND gate 610 and the signal nodehv from transistor 616.

For example, when the block-select signal has the block-select value (e.g., sel_blk = 1, inverter 612 may generate and output the second control signal vxd_n having a switch-off voltage (e.g., vxd_n = 0 V). If the input signal rd_hvp_relax_n also has a value of 1, NAND gate 610 may generate the signal enhvp_n having a value of 0 and provide the signal enhvp_n to level shifter 608. Level shifter 608 may generate the first control signal vxd having a switch-on voltage based on the signals enhvp_n and nodehv. Since the first control signal vxd has the switch-on voltage and the second control signal vxd_n has the switch-off voltage, the block corresponding to block select circuit 600 is selected as described above with reference to FIG. 5C.

In another example, when the block-select signal has the block-unselect value (e.g., sel_blk = 0), inverter 612 may generate and output the second control signal vxd_n having a switch-on voltage. NAND gate 610 may generate the signal enhvp_n having a value of 1 and provide the signal enhvp_n to level shifter 608. Level shifter 608 may generate the first control signal vxd having a switch-off voltage based on the signals enhvp_n and nodehv. Since the first control signal vxd has the switch-off voltage and the second control signal vxd_n has the switch-on voltage, the block corresponding to block select circuit 600 is unselected as described above with reference to FIG. 5C.

In block select circuit 600 of FIG. 6, the value of the block-select signal sel_blk cannot be stored in block select circuit 600, and may vary when the decoded signals xa, xb, and xc are changed. For example, if another block is to be selected, a different block address corresponding to the other block is sent to a block select circuit corresponding to the other block. Meanwhile, the different block address is also sent to block select circuit 600 corresponding to the current block, causing at least one of the decoded signals xa, xb, and xc in block select circuit 600 to be changed to 0. Then, the value of the block-select signal in block select circuit 600 is changed from the block-select value to the block-unselect value. In this case, the block corresponding to block select circuit 600 and the other block corresponding to the different block address cannot be kept in a selected state at the same time and thus, cannot be erased at the same time. As a result, the two blocks need to be selected and erased one by one, and the total erasing time of the two blocks can be relatively long.

Consistent with some aspects of the present disclosure, the flexible multi-block erasing scheme disclosed herein can select and erase multiple blocks in a same period of time (e.g., simultaneously), so that the total erasing time of the multiple blocks can be reduced. As a result, the performance of the memory device can be improved. Example implementations of a block select circuit in the flexible multi-block erasing scheme disclosed herein are described below with reference to FIGS. 7A-7C.

FIG. 7A illustrates a circuit diagram of a block select circuit 700, according to some aspects of the present disclosure. Block select circuit 700 can be an example implementation of block select circuit 532 of FIGS. 5B and 5C. Block select circuit 700 may include address decoding circuit 602, an AND gate 702, a block address latch 704, subcircuit 606, and level shifter 608. Address decoding circuit 602, subcircuit 606, and level shifter 608 are described above with reference to FIG. 6, and a similar description will not be repeated herein.

Address decoding circuit 602 may be configured to receive a block address from control logic 512 and generate decoded signals xa, xb, and xc based on the block address. Address decoding circuit 602 may be coupled to AND gate 702 to provide the decoded signals xa, xb, and xc as inputs to AND gate 702. AND gate 702 may then generate a select signal sel based on the decoded signals. For example, if the block address received from control logic 512 is a block address of a block corresponding to block select circuit 700, indicating that the block corresponding to block select circuit 700 is to be selected, address decoding circuit 602 may generate the decoded signals each of which has a value of 1 (e.g., xa=1, xb=1, and xc=1). Then, AND gate 702 may generate and output the select signal sel having a select value (e.g., sel = 1). Alternatively, if the block address received from control logic 512 is not the block address of the block corresponding to block select circuit 700, indicating that the block corresponding to block select circuit 700 is not to be selected, address decoding circuit 602 may generate the decoded signals with at least one of the decoded signals having a value of 0 (e.g., xa=0, or xb=0, or xc=0). Then, AND gate 702 may generate and output the select signal sel having un unselect value (e.g., sel = 0).

In some implementations, address decoding circuit 602 may receive, from control logic 512, a select-all-block signal indicating that all blocks of the memory device are to be selected. Responsive to receiving the select-all-block signal, address decoding circuit 602 may generate the decoded signals, each of which has a value of 1 (e.g., xa=1, xb=1, and xc=1). Then, AND gate 702 may generate and output the select signal sel having the select value.

Block address latch 704 may include a latch 706 and transistors 708 and 710. A first end of latch 706 may be coupled to a drain of transistor 708, and a second end of latch 706 is coupled to subcircuit 606 and configured to provide a block-select signal sel_blk to subcircuit 606. A gate of transistor 708 is coupled to AND gate 702 and configured to receive the select signal sel. A source of transistor 708 is configured to receive a signal vssx. A gate of transistor 710 is configured to receive a reset signal sel_blk_rst, a source of transistor 710 is configured to receive the signal vssx, and a drain of transistor 710 is coupled to the second end of latch 706.

In some implementations, control logic 512 may generate and send the reset signal sel_blk_rst to block select circuit 700, causing block address latch 704 to be reset to an unselect state (e.g., the block-select signal sel_blk is reset to have a block-unselect value, e.g., sel_blk=0, and a signal unsel_blk at the first end of latch 706 is reset to have a value of 1, e.g., unsel_blk=1). For example, transistor 710 is turned on responsive to receiving the reset signal sel_blk_rst, and then, the block-select signal sel_blk is set to be sel_blk=vssx= 0. As a result, block address latch 704 is reset to the unselect state with the block-select signal sel_blk having the block-unselect value.

Next, if the block corresponding to block select circuit 700 is to be selected by control logic 512, then the decoded signals are equal to 1 (e.g., xa=xb=xc=1), and AND gate 702 outputs the select signal sel having the select voltage, causing transistor 708 to be turned on. Since transistor 708 is turned on, the first end of latch 706 is set to be the signal vssx (e.g., unsel_blk = vssx = 0), causing the value of the block-select signal sel_blk at the second end of latch 706 to be pulled up from the block-unselect value to the block-select value. As a result, the block corresponding to block select circuit 700 can be selected, as described above with reference to FIG. 5C.

Alternatively, if the block corresponding to block select circuit 700 is not to be selected, then at least one of the decoded signals xa, xb, and xc is equal to 0, and AND gate 702 outputs the select signal sel having the unselect voltage, causing transistor 708 to be switched off. Since transistor 708 is switched off, the signal unsel_blk at the first end of latch 706 remains to be unsel_blk=1, and the value of the block-select signal sel_blk at the second end of latch 706 remains to be the block-unselect value (e.g., sel_blk = 0). As a result, the block corresponding to block select circuit 700 is unselected, as described above with reference to FIG. 5C.

In block select circuit 700 of FIG. 7A, the value of the block-select signal sel_blk may be stored in block address latch 704 and does not vary when the decoded signals xa, xb, and xc are changed. That is, when the block corresponding to block select circuit 700 is selected, the block-select value of the block-select signal sel_blk can be stored in block select circuit 700. Then, if the decoded signals xa, xb, and xc are changed because another block is selected, the value of the block-select signal sel_blk in block select circuit 700 may still be the block-select value. In this case, the block corresponding to block select circuit 700 and the other selected block can be kept in the selected state at the same time, and then, the two blocks can be erased simultaneously. As a result, the total erasing time of the two blocks can be reduced.

FIG. 7B illustrates another circuit diagram of a block select circuit 740, according to some aspects of the present disclosure. Block select circuit 740 may include an NAND gate 744, an NOR gate 748, a block labeling latch 742, block address latch 704, and subcircuit 606. Like block select circuit 700 of FIG. 7A, block select circuit 740 may also include: (1) address decoding circuit 602 coupled to NAND gate 744 and configured to provide decoded signals xa, xb, and xc to NAND gate 744; and (2) level shifter 608 coupled to subcircuit 606 to receive the signals enhvp_n and nodehv from subcircuit 606 and configured to generate the first control signal vxd based on the signals enhvp_n and nodehv. Address decoding circuit 602, subcircuit 606, and level shifter 608 are described above with reference to FIG. 6, and a similar description will not be repeated herein.

NAND gate 744 may generate a pre-select signal selpre_n based on the decoded signals received from address decoding circuits 602, and provide the pre-select signal selpre_n as a first input to NOR gate 748. For example, if each of the decoded signals has a value of 1 (e.g., xa=1, xb=1, and xc=1), indicating that the block corresponding to block select circuit 740 is to be selected, then NAND gate 744 may generate and output the pre-select signal selpre_n having a value of 0. Alternatively, if at least one of the decoded signals has a value of 0 (e.g., xa=0, or xb=0, or xc=0), indicating that the block corresponding to block select circuit 740 is not to be selected, then NAND gate 744 may generate and output the pre-select signal selpre_n having a value of 1.

Block labeling latch 742 may be configured to label whether the block corresponding to block select circuit 740 is a functioning block (e.g., a good block) or a bad block. Block labeling latch 742 may include, for example, a latch 746, a NOR gate 750, and transistors 752, 754, 756, and 758. A first end of latch 746 may be coupled to a drain of transistor 752, and a second end of latch 746 may be coupled to a drain of transistor 754. NOR gate 750 may be coupled to latch 746 and receive a first block-labeling signal blk_good from the first end of latch 746 as a first input. NOR gate 750 may also receive a signal blat+bypass as a second input. NOR gate 750 may generate a block-labeling output signal label_out based on the first block-labeling signal blk_good and the signal blat+bypass, and provide the block-labeling output signal label_out as a second input to NOR gate 748. A gate of transistor 752 is configured to receive a functioning-block setting signal Set. A source of transistor 752 is coupled to a drain of transistor 756. A source of transistor 754 is also coupled to the drain of transistor 756, and a drain of transistor 754 is configured to receive a bad-block setting signal rst. A source of transistor 756 is coupled to a drain of transistor 758, and a gate of transistor 756 is coupled to an output end of NOR gate 748 to receive a select signal sel outputted from NOR gate 748.

In some implementations, to label the block corresponding to block select circuit 740 to be a bad block, the bad-block setting signal rst may be received from control logic 512 to reset a second block-labeling signal blk_bad at the second end of latch 746 to be 1 (e.g., blk_bad=1). The first block-labeling signal blk_good is set to be 0 (e.g., blk_good=0). Then, if the signal blat+bypass has a value of 0, NOR gate 750 may generate the block-labeling output signal label_out having a value of 1. That is, when the block corresponding to block select circuit 740 is labeled as a bad block, the block-labeling output signal label_out may have a value of 1. NOR gate 748 may then generate the select signal sel having the unselect value of 0, no matter whether the pre-select signal selpre_n has a value of 0 or 1 (e.g., no matter whether the block corresponding to block select circuit 740 is to be selected or not by control logic 512). Then, since the select signal sel has the unselect value of 0, the block-select signal sel_blk has a block-unselect value (e.g., 0), causing the block corresponding to block select circuit 740 to be unselected, as described above with reference to FIG. 6 and 7A. That is, the block that corresponds to block select circuit 740 and is labeled as a bad block cannot be selected.

In some implementations, to label the block corresponding to block select circuit 740 to be a functioning block (e.g., a good block), the functioning-block setting signal Set may be received from control logic 512 to set the first block-labeling signal blk_good at the first end of latch 746 to be 1 (e.g., blk_good=1). The second block-labeling signal blk_bad is set to be 0 (e.g., blk_bad=0). Then, no matter whether the signal blat+bypass has a value of 0 or 1, NOR gate 750 may generate the block-labeling output signal label_out having a value of 0. That is, when the block corresponding to block select circuit 740 is labeled as a functioning block, the block-labeling output signal label_out may have a value of 0. NOR gate 748 may then generate the select signal sel having a select value of 1 if the pre-select signal selpre_n has a value of 0 (e.g., if the block corresponding to block select circuit 740 is to be selected by control logic 512). Then, since the select signal sel has the select value of 1, the block-select signal sel_blk has a block-select value (e.g., 1), causing the block corresponding to block select circuit 740 to be selected, as described above with reference to FIGS. 6 and 7A.

In block select circuit 740 of FIG. 7B, the value of the block-select signal sel_blk may be stored in block address latch 704 and does not vary when the decoded signals xa, xb, and xc are changed. That is, when the block corresponding to block select circuit 740 is selected, the block-select value of the block-select signal sel_blk can be stored in block select circuit 740. Then, if the decoded signals xa, xb, and xc are changed due to another block being selected, the block-select signal sel_blk in block select circuit 740 may still have the block-select value. In this case, the block corresponding to block select circuit 740 and the other selected block can be kept in the selected state at the same time, and then, the two blocks can be erased simultaneously. As a result, the total erasing time of the two blocks can be reduced.

FIG. 7C illustrates still another circuit diagram of a block select circuit 760, according to some aspects of the present disclosure. Block select circuit 760 may include NAND gate 744, a NOR gate 762, block labeling latch 742, and subcircuit 606. Like block select circuit 700 of FIG. 7A, block select circuit 760 may also include: (1) address decoding circuit 602 coupled to NAND gate 744 and configured to provide the decoded signals xa, xb, and xc to NAND gate 744; and (2) level shifter 608 coupled to subcircuit 606 to receive the signals enhvp_n and nodehv from subcircuit 606 and configured to generate the first control signal vxd based on the signals enhvp_n and nodehv.

Similar to FIG. 7B, if a block address received from control logic 512 is a block address of a block corresponding to block select circuit 760 (e.g., the block corresponding to block select circuit 760 is to be selected), then NAND gate 744 may generate and output a pre-select signal selpre_n having a value of 0. Alternatively, if the block address received from control logic 512 is not the block address of the block corresponding to block select circuit 760 (e.g., the block corresponding to block select circuit 760 is not to be selected), then NAND gate 744 may generate and output the pre-select signal selpre_n having a value of 1.

Also similar to FIG. 7B, when the block corresponding to block select circuit 760 is labeled as a bad block, block labeling latch 742 may generate and output a block-labeling output signal label_out which has a value of 1. NOR gate 762 of FIG. 7C may then generate a block-select signal sel_blk having a block-unselect value (e.g., 0), no matter whether the pre-select signal selpre_n has a value of 0 or 1 (e.g., no matter whether the block corresponding to block select circuit 760 is to be selected or not by control logic 512). That is, the block corresponding to block select circuit 760 cannot be selected because it is labeled as a bad block.

Also similar to FIG. 7B, when the block corresponding to block select circuit 760 is labeled as a functioning block, block labeling latch 742 may generate and output the block-labeling output signal label_out which has a value of 0. NOR gate 762 of FIG. 7C may then generate the block-select signal sel_blk having a block-select value (e.g., 1) if the pre-select signal selpre_n has a value of 0 (e.g., if the block corresponding to block select circuit 760 is to be selected by control logic 512). The block-select signal sel_blk having the block-select value may cause the block corresponding to block select circuit 760 to be selected, as described above with reference to FIGS. 6 and 7A.

Unlike block select circuit 700 of FIG. 7A and block select circuit 740 of FIG. 7B, block select circuit 760 of FIG. 7C does not include any block address latch 704 for storing the value of the block-select signal sel_blk. However, with the application of block select circuit 760, multiple blocks of the memory device can also be kept in a selected state simultaneously, as described below in more detail. As a result, the multiple blocks can be erased in the same period of time (e.g., simultaneously), and the total erasing time of the multiple blocks can be reduced.

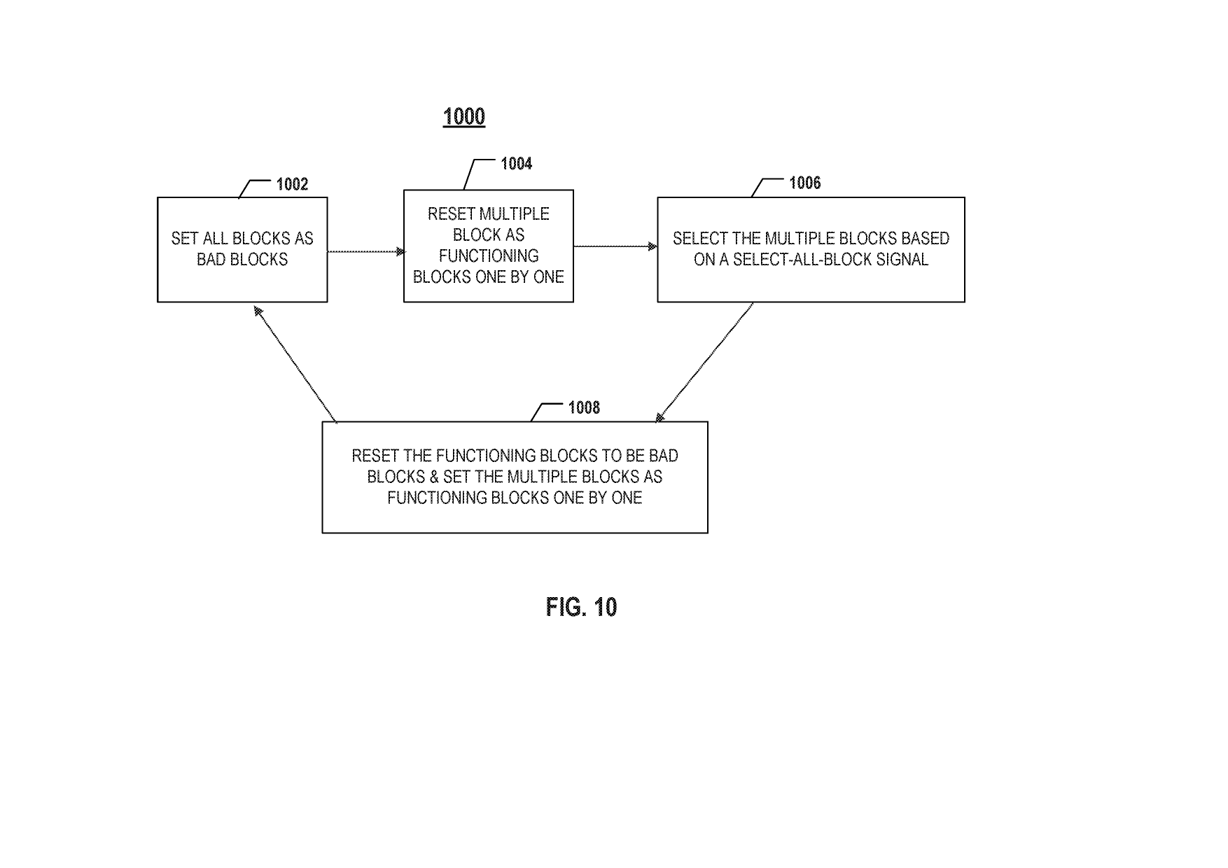

Consistent with some aspects of the present disclosure, a memory device disclosed herein may include: (1) a memory cell array including a plurality of blocks (e.g., memory cell array 401 including blocks 404); and (2) a peripheral circuit (e.g., peripheral circuit 402) coupled to the plurality of blocks. The plurality of blocks may include a first block, a second block, and a third block located between the first and second blocks in a plane of the memory device. That is, the first block and the second block are discontinuous blocks. Examples of the first, second, and third blocks are illustrated below in FIG. 10. The peripheral circuit may include: (1) a plurality of block select circuits corresponding to the plurality of blocks, respectively; and (2) control logic (e.g., control logic 512) configured to control an operation of the plurality of block select circuits.

Consistent with some aspects of the present disclosure, the peripheral circuit may be configured to select the first and second blocks from the plurality of blocks, where the third block is unselected while the first and second blocks are selected. In a first example, the plurality of block select circuits may be a plurality of block select circuits 700 as shown in FIG. 7A. The plurality of block select circuits 700 may include a plurality of block address latches 704, respectively. Initially, the peripheral circuit can be configured to unselect the plurality of blocks. For instance, control logic 512 may generate and send a reset signal sel_blk_rst to the plurality of block select circuits 700, respectively. Responsive to receiving the reset signal, the plurality of block select circuits 700 may reset the plurality of block address latches 704 to an unselect state, respectively (e.g., in each block address latch 704, a block-select signal sel_blk is reset to have a block-unselect value, as described above with reference to FIG. 7A). As a result, the plurality of blocks (including the first, second and third blocks) are unselected. Next, for each block in the first and second blocks, control logic 512 may send a block address of the corresponding block to a block select circuit 700 associated with the corresponding block, causing block select circuit 700 to generate a block-select signal having a block-select value to select the corresponding block, as described above with reference to FIG. 7A. The block-select signal having the block-select value may be stored in a block address latch 704 of block select circuit 700. As a result, the first and second blocks can be selected.

In a second example, the plurality of block select circuits may be a plurality of block select circuits 740 as shown in FIG. 7B. The plurality of block select circuits 740 may include a plurality of block address latches 704 and a plurality of block labeling latches 742, respectively. Each block labeling latch 742 may be used to label whether a corresponding block is a functioning block or a bad block, as described above with reference to FIG. 7B. For instance, block labeling latch 742 may have a functioning block state indicating that the corresponding block is a functioning block (e.g., a first block-labeling signal blk_good=1, or a second block-labeling signal blk_bad=0). Alternatively, block labeling latch 742 may have a bad block state indicating that the corresponding block is a bad block (e.g., the first block-labeling signal blk_good=0, or the second block-labeling signal blk_bad=1).

Initially, the peripheral circuit can be configured to unselect the plurality of blocks by performing operations like those described above with reference to the first example. Next, for each block in the first and second blocks, control logic 512 may send a block address of the corresponding block to a block select circuit 740 associated with the corresponding block. Responsive to (1) receiving the block address of the corresponding block and (2) a state of a block labeling latch 742 in block select circuit 740 indicating that the corresponding block is a functioning block, block select circuit 740 associated with the corresponding block may generate a block-select signal having a block-select value to select the corresponding block, as described above with reference to FIG. 7B. The block-select signal having the block-select value may be stored in a block address latch 704 of block select circuit 740. As a result, the first and second blocks can be selected.

In a third example, the plurality of block select circuits may be a plurality of block select circuits 760 as shown in FIG. 7C. The plurality of block select circuits 760 may include a plurality of block labeling latches 742, respectively. Initially, the peripheral circuit can be configured to label the plurality of blocks as bad blocks. For instance, control logic 512 may generate and send a bad-block setting signal rst to the plurality of block select circuits 760, causing the plurality of block select circuits 760 to reset the plurality of block labeling latches 742 to a bad block state, respectively, as described above with reference to FIG. 7C. As a result, the plurality of blocks can be labeled as bad blocks.

Next, the peripheral circuit may relabel the first and second blocks to be selected as functioning blocks. For instance, for each block in the first and second blocks, control logic 512 may generate and send a functioning-block setting signal Set to a block select circuit 760 associated with the corresponding block, causing block select circuit 760 to set a corresponding block labeling latch 742 to a functioning block state, so that the corresponding block is relabeled as a functioning block.

Subsequently, the peripheral circuit may select the first and second blocks relabeled as the functioning blocks based on a select-all-block signal. For instance, control logic 512 may generate and send the select-all-block signal to the plurality of block select circuits 760. Since the first and second blocks are relabeled as functioning blocks, first block select circuits 760 corresponding to the first and second blocks may generate first block-select signals having a block-select value to select the first and second blocks, respectively, responsive to receiving the select-all-block signal. On the other hand, since the remaining blocks in the plurality of blocks are labeled as bad blocks, second block select circuits 760 corresponding to the remaining blocks may generate second block-select signals having a block-unselect value to unselect the remaining blocks, respectively, responsive to receiving the select-all-block signal. As a result, the first and second blocks are selected, whereas the remaining blocks are unselected.

Consistent with some aspects of the present disclosure, the peripheral circuit may also be configured to perform a first erase operation on the first and second blocks in a first period of time. Specifically, the peripheral circuit can be configured to apply an erase voltage to erase the first and second blocks in the first period of time while the first and second blocks are being selected. For example, the peripheral circuit can apply an erase word line voltage to first word lines coupled to the first block and second word lines coupled to the second block in the first period of time. Then, the peripheral circuit can apply an erase voltage to a common source line coupled to the first and second blocks to erase the first and second blocks in the first period of time (e.g., to erase the first and second blocks simultaneously).

Next, the peripheral circuit can also be configured to apply a verify voltage to verify the erasing of the first and second blocks in the first period of time. For example, the peripheral circuit can apply a verify voltage to the first word lines coupled to the first block and the second word lines coupled to the second block to verify the erasing of the first and second blocks in the first period of time. That is, the peripheral circuit can simultaneously apply a verify voltage to the first word lines coupled to the first block and the second word lines coupled to the second block to verify the erasing of the first and second blocks.

In another example, the peripheral circuit can verify the erasing of the first and second blocks one block by one block. Specifically, the peripheral circuit can select the first block and unselect the second block. For example, since the first and second blocks are already selected, the peripheral circuit can keep the first block in the selected state and only unselect the second block (e.g., by performing operations like those described above with reference to FIGS. 7A-7C). Next, the peripheral circuit can apply the verify voltage to the first word lines coupled to the first block to verify the erasing of the first block. Further, the peripheral circuit can unselect the first block and select the second block (e.g., by performing operations like those described above with reference to FIGS. 7A-7C). Subsequently, the peripheral circuit can apply the verify voltage to the second word lines coupled to the second block to verify the erasing of the second block.

In some implementations, the peripheral circuit may be further configured to unselect the first block and the second block. The peripheral circuit may select the third block from the memory device. The peripheral circuit may perform a second erase operation on the third block in a second period of time, which is different from the first period of time.

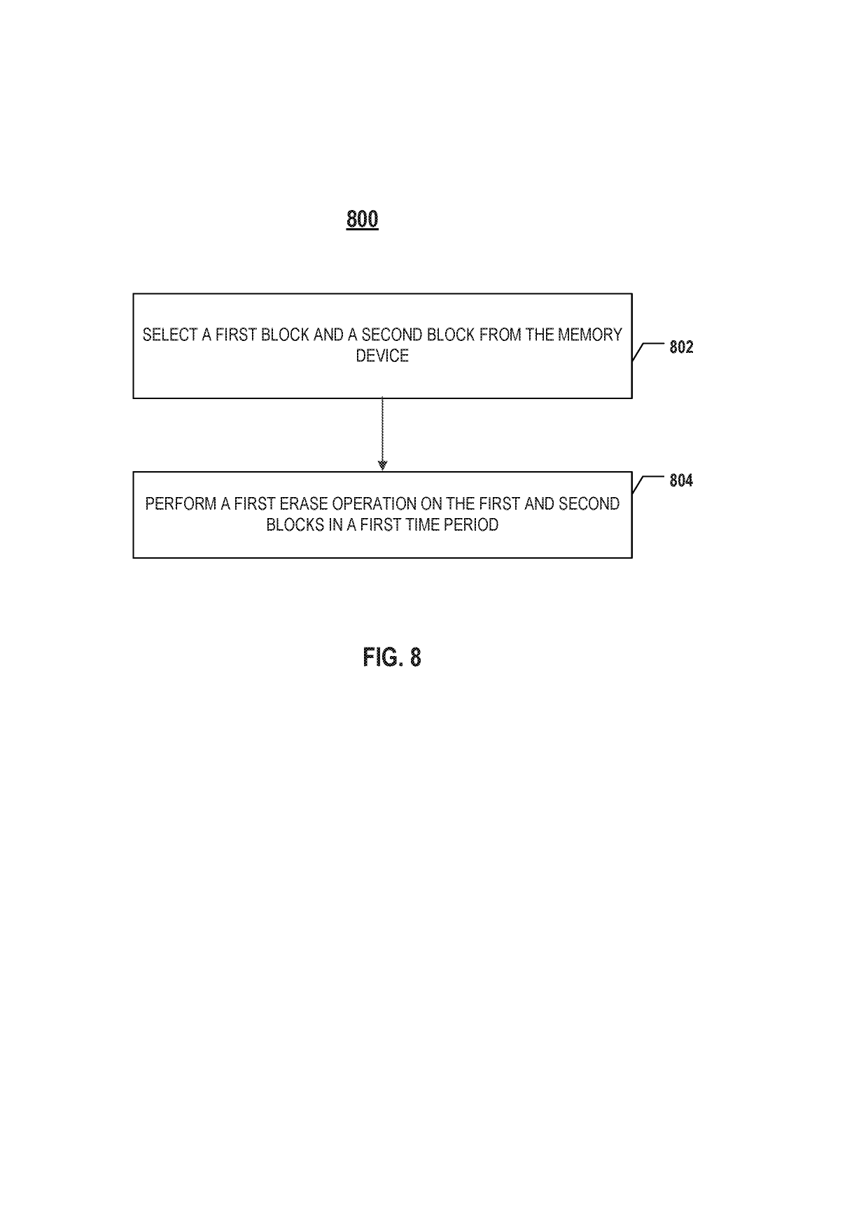

FIG. 8 illustrates a flowchart of a method 800 for operating a memory device, according to some examples of the present disclosure. Method 800 may be performed by a peripheral circuit (e.g., peripheral circuit 402) of the memory device. It is understood that the operations shown in method 800 may not be exhaustive and that other operations can be performed as well before, after, or between any of the illustrated operations. Further, some of the operations may be performed simultaneously, or in a different order than shown in FIG. 8.

The memory device of FIG. 8 can be any memory device disclosed herein, such as memory device 104 of FIG. 1, non-volatile memory device 302 of FIG. 3, or memory device 400 of FIG. 4. The memory device may include the peripheral circuit and a plurality of blocks coupled to the peripheral circuit. The plurality of blocks may include a first block, a second block, and a third block located between the first and second blocks. The first, second and third blocks are in a plane of the memory device. The peripheral circuit may include a plurality of block select circuits.

Method 800 may begin with operation 802 in which the peripheral circuit may select the first block and the second block from the memory device. The third block is unselected while the first and second blocks are being selected.

In a first example, the peripheral circuit may include a plurality of block select circuits 700 as shown in FIG. 7A. The plurality of block select circuits 700 may include a plurality of block address latches 704, respectively. Initially, the peripheral circuit may unselect the plurality of blocks. For example, by performing operations like those described above with reference to FIG. 7A, the peripheral circuit may reset the plurality of block address latches 704 to an unselect state (e.g., in each block address latch 704, a corresponding block-select signal sel_blk is set to be a block-unselect value), so that the plurality of blocks are unselected. Next, for each block in the first and second blocks, the peripheral circuit may generate a block-select signal having a block-select value to select the corresponding block responsive to receiving a block address of the corresponding block. The block-select signal can be stored in a block address latch 704 associated with the corresponding block.

In a second example, the peripheral circuit may include a plurality of block select circuits 740 as shown in FIG. 7B. The plurality of block select circuits 740 may include a plurality of block address latches 704 and a plurality of block labeling latches 742, respectively. Initially, the peripheral circuit may unselect the plurality of blocks by performing operations like those described above with reference to the first example. Next, for each block in the first and second blocks, the peripheral circuit may generate a block-select signal having a block-select value to select the corresponding block responsive to (1) receiving a block address of the corresponding block and (2) a state of a block labeling latch 742 associated with the corresponding block indicating that the corresponding block is a functioning block.

In a third example, the peripheral circuit may include a plurality of block select circuits 760 as shown in FIG. 7C. The plurality of block select circuits 760 may include a plurality of block labeling latches 742, respectively. Initially, the peripheral circuit may label the plurality of blocks as bad blocks. For instance, by performing operations like those described above with reference to FIG. 7C, the peripheral circuit may set a plurality of block labeling latches 742 associated with the plurality of blocks to a bad block state, so that the plurality of blocks are labeled as bad blocks.

Next, the peripheral circuit may relabel the first and second blocks as functioning blocks. For instance, for each block in the first and second blocks, the peripheral circuit may set a block labeling latch 742 associated with the corresponding block to a functioning block state, so that the corresponding block is relabeled as a functioning block.

Subsequently, the peripheral circuit may select the first and second blocks relabeled as the functioning blocks based on a select-all-block signal. For instance, based on the select-all-block signal, the peripheral circuit may generate first block-select signals having a block-select value to select the first and second blocks, respectively, and generate second block-select signals having a block-unselect value to unselect remaining blocks in the plurality of blocks, respectively. Operations like those described above with reference to FIG. 7C can be performed to select the first and second blocks, and a similar description will not be repeated herein.

Method 800 may proceed to operation 804, in which the peripheral circuit can perform a first erase operation on the first and second blocks in a first time period. In some implementations, the peripheral circuit may apply an erase voltage to erase the first and second blocks in the first period of time while the first and second blocks are being selected. For example, the peripheral circuit may apply an erase word line voltage to first word lines coupled to the first block and second word lines coupled to the second block in the first period of time. The peripheral circuit may apply the erase voltage to a common source line coupled to the first and second blocks to erase the first and second blocks in the first period of time.

Next, the peripheral circuit may apply a verify voltage to verify the erasing of the first and second blocks in the first period of time. For example, the peripheral circuit may apply a verify voltage to the first word lines coupled to the first block and the second word lines coupled to the second block simultaneously to verify the erasing of the first and second blocks in the first period of time, while the first and second blocks are being selected. In another example, the peripheral circuit may select the first block and unselect the second block. The peripheral circuit may apply the verify voltage to the first word lines coupled to the first block to verify the erasing of the first block. Then, the peripheral circuit may unselect the first block and select the second block. The peripheral circuit may apply the verify voltage to the second word lines coupled to the second block to verify the erasing of the second block.

In some implementations, the peripheral circuit may be further configured to unselect the first and second blocks. The peripheral circuit may select the third block from the memory device. The peripheral circuit may perform a second erase operation on the third block in a second period of time that is different from the first period of time.

FIG. 9 illustrates a plurality of blocks included in a memory device, according to some aspects of the present disclosure. The plurality of blocks may include a first block, a second block, and a third block located between the first and second blocks in the same plane of the memory device. The first and second blocks may be referred to as discontinuous blocks. The memory device can be any memory device disclosed herein, such as memory device 104 of FIG. 1, non-volatile memory device 302 of FIG. 3, or memory device 400 of FIG. 4.

Table 1 depicts two planes (Plane 0, Plane 1) of the memory device. For example, Plane 0 may include blocks blk00, blk01, blk 02, ..., blk0x, ..., blk0y, ..., and blk 0z. Examples of the first, second, and third blocks are illustrated in Table 2. For example, the first block can be the block blk00 from Plane 0, the second block can be the block blk02 from Plane 0, and the third block can be the block blk01 from Plane 0. The third block blk01 is located between the first block blk00 and the second block blk02.

FIG. 10 illustrates a process 1000 of operating a memory device, according to some aspects of the present disclosure. The memory device can be any memory device disclosed herein, such as memory device 104 of FIG. 1, non-volatile memory device 302 of FIG. 3, or memory device 400 of FIG. 4. Process 1000 may be performed by a peripheral circuit of the memory device. The peripheral circuit may include a plurality of block select circuits 760 as shown in FIG. 7C. The plurality of block select circuits 760 may include a plurality of block labeling latches 742, respectively.

Process 1000 may begin with operation 1002, in which the peripheral circuit may set all blocks of the memory device as bad blocks. For instance, by performing operations like those described above with reference to FIG. 7C, the peripheral circuit may set block labeling latches 742 associated with the blocks to a bad block state, so that the blocks in the memory device are labeled as bad blocks.

Process 1000 may proceed to operation 1004 in which the peripheral circuit may reset multiple blocks from the blocks as functioning blocks one by one. The multiple blocks are discontinuous blocks to be selected for an erase operation. For instance, for each block in the multiple blocks, the peripheral circuit may set a block labeling latch 742 associated with the corresponding block to a functioning block state, so that the corresponding block is relabeled as a functioning block.

Process 1000 may proceed to operation 1006 in which the peripheral circuit may select the multiple blocks relabeled as the functioning blocks based on a select-all-block signal. Then, the peripheral circuit may apply an erase voltage to erase the multiple blocks in the first period of time while the multiple blocks are being selected. For example, the peripheral circuit may apply an erase word line voltage to word lines coupled to the multiple blocks in the first period of time. The peripheral circuit may also apply the erase voltage to a common source line coupled to the multiple blocks to erase the multiple blocks in the first period of time while the first and second blocks are being selected.

Process 1000 may proceed to operation 1008 in which the peripheral circuit may reset the functioning blocks (e.g., the multiple blocks) to be bad blocks again. Then, the peripheral circuit may set the multiple blocks as functioning blocks again one by one. For example, the peripheral circuit may set a first one of the multiple blocks to be a functioning block and apply a verify voltage to verify the erasing of the first one of the multiple blocks. Next, the peripheral circuit may set the first one of the multiple blocks to be a bad block again, set a second one of the multiple blocks to be a functioning block, and apply a verify voltage to verify the erasing of the second one of the multiple blocks. By performing similar operations, the peripheral circuit may verify the erasing of the multiple blocks one by one.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A method of operating a memory device, comprising:
selecting a first block and a second block from the memory device, wherein the memory device comprises a plurality of blocks comprising the first block, the second block, and a third block located between the first and second blocks in a plane of the memory device, and wherein the third block is unselected while the first and second blocks are being selected; and
performing a first erase operation on the first and second blocks in a first period of time.

2. The method of claim 1, further comprising:
selecting the third block from the memory device; and
performing a second erase operation on the third block in a second period of time that is different from the first period of time.

3. The method of claim 1, wherein the memory device comprises a peripheral circuit coupled to the plurality of blocks, and selecting the first block and the second block from the memory device comprises:
unselecting, by the peripheral circuit, the plurality of blocks; and
for each block in the first and second blocks,
responsive to receiving a block address of the corresponding block, generating, by the peripheral circuit, a block-select signal having a block-select value to select the corresponding block, wherein the block-select signal is stored in a block address latch associated with the corresponding block.

4. The method of claim 3, wherein unselecting the plurality of blocks comprises:
resetting, by the peripheral circuit, a plurality of block address latches associated with the plurality of blocks to an unselect state, so that the plurality of blocks are unselected.

5. The method of claim 3, wherein generating the block-select signal further comprises:
responsive to receiving the block address of the corresponding block and a state of a block labeling latch associated with the corresponding block indicating that the corresponding block is a functioning block, generating the block-select signal having the block-select value.

6. The method of claim 1, wherein the memory device comprises a peripheral circuit coupled to the plurality of blocks, and selecting the first block and the second block from the memory device comprises:
labeling, by the peripheral circuit, the plurality of blocks as bad blocks;
relabeling, by the peripheral circuit, the first and second blocks as functioning blocks; and
selecting, by the peripheral circuit, the first and second blocks relabeled as the functioning blocks based on a select-all-block signal.

7. The method of claim 6, wherein:
labeling the plurality of blocks as the bad blocks comprises:
setting, by the peripheral circuit, a plurality of block labeling latches associated with the plurality of blocks to a bad block state, so that the plurality of blocks are labeled as the bad blocks; and
relabeling the first and second blocks as the functioning blocks comprises:
for each block in the first and second blocks,
setting, by the peripheral circuit, a block labeling latch associated with the corresponding block to a functioning block state, so that the corresponding block is relabeled as a functioning block.

8. The method of claim 6, wherein selecting the first and second blocks relabeled as the functioning blocks based on the select-all-block signal comprises:
generating, by the peripheral circuit, first block-select signals having a block-select value to select the first and second blocks, respectively, based on the select-all-block signal; and
generating, by the peripheral circuit, second block-select signals having a block-unselect value to unselect remaining blocks in the plurality of blocks, respectively, based on the select-all-block signal.

9. The method of claim 1, wherein performing the first erase operation on the first and second blocks in the first period of time comprises:
applying an erase voltage to erase the first and second blocks in the first period of time while the first and second blocks are being selected; and
applying a verify voltage to verify the erasing of the first and second blocks in the first period of time.

10. A memory device, comprising:
a memory cell array comprising a plurality of blocks, wherein the plurality of blocks comprises a first block, a second block, and a third block located between the first and second blocks in a plane of the memory device;
a peripheral circuit coupled to the memory cell array, and configured to:
select the first and second blocks from the plurality of blocks, wherein the third block is unselected while the first and second blocks are being selected; and
perform a first erase operation on the first and second blocks in a first period of time.

11. The memory device of claim 10, wherein the peripheral circuit is further configured to:
select the third block from the memory device; and
perform a second erase operation on the third block in a second period of time that is different from the first period of time.

12. The memory device of claim 10, wherein the peripheral circuit comprises:
a plurality of block select circuits corresponding to the plurality of blocks, respectively; and
control logic configured to control an operation of the plurality of block select circuits.

13. The memory device of claim 12, wherein the plurality of block select circuits comprise a plurality of block address latches, respectively, and to select the first and second blocks from the plurality of blocks, the peripheral circuit is further configured to:
unselect the plurality of blocks; and
for each block in the first and second blocks,
send, by the control logic, a block address of the corresponding block to a block select circuit associated with the corresponding block; and
generate, by the block select circuit, a block-select signal having a block-select value to select the corresponding block responsive to receiving the block address of the corresponding block, wherein the block-select signal is stored in a block address latch of the block select circuit.

14. The memory device of claim 13, wherein to unselect the plurality of blocks, the peripheral circuit is further configured to:
generate and send, by the control logic, a reset signal to the plurality of block select circuits, respectively; and
reset, by the plurality of block select circuits, the plurality of block address latches in the plurality of block select circuits to an unselect state, respectively, responsive to receiving the reset signal, so that the plurality of blocks are unselected.

15. The memory device of claim 13, wherein the plurality of block select circuits further comprise a plurality of block labeling latches, respectively, and to generate the block-select signal, the block select circuit is configured to:
responsive to receiving the block address of the corresponding block and a state of a block labeling latch in the block select circuit indicating that the corresponding block is a functioning block, generate the block-select signal having the block-select value.

16. The memory device of claim 12, wherein the plurality of block select circuits comprise a plurality of block labeling latches, respectively, and to select the first and second blocks from the plurality of blocks, the peripheral circuit is further configured to:
label the plurality of blocks as bad blocks;
relabel the first and second blocks as functioning blocks; and
select the first and second blocks relabeled as the functioning blocks based on a select-all-block signal.

17. The memory device of claim 16, wherein:
to label the plurality of blocks as the bad blocks, the peripheral circuit is further configured to:
generate and send, by the control logic, a bad-block setting signal to the plurality of block select circuits, respectively; and
set, by the plurality of block select circuits, the plurality of block labeling latches to a bad block state, respectively, responsive to receiving the bad-block setting signal, so that the plurality of blocks are labeled as the bad blocks; and
to relabel the first and second blocks as the functioning blocks, the peripheral circuit is further configured to:
for each block in the first and second blocks,
generate and send, by the control logic, a functioning-block setting signal to a block select circuit associated with the corresponding block; and
set, by the block select circuit, a block labeling latch in the block select circuit to a functioning block state, so that the corresponding block is relabeled as a functioning block.

18. The memory device of claim 16, wherein to select the first and second blocks relabeled as the functioning blocks based on the select-all-block signal, the peripheral circuit is further configured to:
generate and send, by the control logic, the select-all-block signal to the plurality of block select circuits;
generate, by first block select circuits corresponding to the first and second blocks, first block-select signals having a block-select value to select the first and second blocks, respectively, responsive to receiving the select-all-block signal; and
generate, by second block select circuits corresponding to remaining blocks in the plurality of blocks, second block-select signals having a block-unselect value to unselect the remaining blocks, respectively, responsive to receiving the select-all-block signal.

19. The memory device of claim 11, wherein to perform the first erase operation on the first and second blocks in the first period of time, the peripheral circuit is further configured to:
apply an erase voltage to erase the first and second blocks in the first period of time while the first and second blocks are being selected; and
apply a verify voltage to verify the erasing of the first and second blocks in the first period of time.

20. A system, comprising:
a memory device, comprising:
a memory cell array comprising a plurality of blocks, wherein the plurality of blocks comprises a first block, a second block, and a third block located between the first and second blocks in a plane of the memory device;
a peripheral circuit coupled to the memory cell array, and configured to:
select the first and second blocks from the plurality of blocks, wherein the third block is unselected while the first and second blocks are being selected; and
perform a first erase operation on the first and second blocks in a first period of time; and
a memory controller coupled to the memory device and configured to control an operation of the memory device.
.
